(19) United States
(12) Patent Application Publication
(10) Pub. No.: US 2023/0284454 A1
(43) Pub. Date: Sep. 7, 2023

(54) MEMORY CELL AND METHODS THEREOF

(71) Applicant: Ferroelectric Memory GmbH, Dresden (DE)

(72) Inventors: Johannes Ocker, Dresden (DE); Stefan Ferdinand Müller, Dresden (DE); Patrick Polakowski, Dresden (DE)

(21) Appl. No.: 18/117,357

(22) Filed: Mar. 3, 2023

Related U.S. Application Data
(62) Division of application No. 17/072,079, filed on Oct. 16, 2020.

(51) Int. Cl. H10B 51/30; H01L 29/78; H01L 29/51; H01L 29/417; H01L 29/66; H01L 29/06; H01L 29/423; H01L 29/786

(52) U.S. Cl. CPC H10B 51/30; H01L 28/60; H01L 29/0673; H01L 29/41733; H01L 29/41791; H01L 29/42392; H01L 29/516; H01L 29/6684; H01L 29/78391; H01L 29/7851; H01L 29/78696

(57) ABSTRACT

A memory cell includes a capacitive memory structure comprising a first electrode; a field-effect transistor structure comprising a gate electrode; one or more insulator layers; one or more source/drain contact structures embedded in the one or more insulator layers to electrically contact the field-effect transistor structure; and a connection structure embedded in at least one of the one or more insulator layers; and one or more electrically insulating structures in addition to the one or more insulator layers configured to prevent a leakage current-induced charging of the first electrode, the gate electrode, and the connection structure, wherein the one or more electrically insulating structures comprise: a memory charge-prevention layer disposed between the first electrode of the capacitive memory structure and at least one of the one or more insulator layers, the memory charge-prevention layer laterally surrounding the first electrode of the capacitive memory structure.

### CROSS-REFERENCE TO RELATED APPLICATIONS

This is a divisional of U.S. Non-Provisional Application 17/072,079, which was filed on Oct. 16, 2020, the entire contents of which are incorporated herein by reference.

### TECHNICAL FIELD

Various aspects relate to a memory cell and methods thereof, e.g. a method for processing a memory cell.

### BACKGROUND

In general, various computer memory technologies have been developed in the semiconductor industry. A fundamental building block of a computer memory may be referred to as memory cell. The memory cell may be an electronic circuit that is configured to store at least one information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained by determining in which of the memory states the memory cell is residing in. At present, various types of memory cells may be used to store data. By way of example, a type of memory cell may include a thin film of ferroelectric material, whose polarization state may be changed in a controlled fashion to store data in the memory cell, e.g. in a non-volatile manner.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows schematically an equivalent circuit diagram of a memory cell, according to various aspects;

FIG. 2 shows schematically a metallization structure, according to various aspects;

FIG. 3A and FIG. 3B each shows schematically a field-effect transistor structure, according to various aspects;

FIG. 3C to FIG. 3F each shows schematically a gate isolation, according to various aspects;

FIG. 4A to FIG. 4E each shows schematically a capacitive memory structure, according to various aspects;

FIG. 5A to FIG. 5G each shows schematically a memory cell, according to various aspects; and

FIG. 6 shows a schematic flow diagram of a method for processing a memory cell, according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a field-effect transistor structure, a capacitive memory structure, or a memory cell). However, it may be understood that aspects described in connection with methods may similarly apply to the devices, and vice versa.

The terms “at least one” and “one or more” may be understood to include any integer number greater than or equal to one, i.e. one, two, three, four, [...], etc. The term “a plurality” or “a multiplicity” may be understood to include any integer number greater than or equal to two, i.e. two, three, four, five, [...], etc.

The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

In the semiconductor industry, the integration of non-volatile memory technologies may be useful for System-on-Chip (SoC) products like microcontrollers (MCU), etc. According to various aspects, a non-volatile memory may be integrated next to a processor core of a processor. As another example, one or more non-volatile memories may be used as part of a mass storage device. In some aspects, a non-volatile memory technology may be based on at least one field-effect transistor (FET) structure. In some aspects, a memory cell may include a field-effect transistor structure and a capacitive memory structure coupled to a gate electrode of the field-effect transistor structure. The amount of charge stored in the capacitive memory structure may influence the threshold voltage(s) of the field-effect transistor structure. The threshold voltage(s) of the field-effect transistor structure may define the memory state the memory cell is residing in. In some aspects, the capacitive memory structure may be a ferroelectric capacitor structure (FeCAP) coupled to a gate electrode of the field-effect transistor structure to provide a ferroelectric field-effect transistor (FeFET) structure. Since a ferroelectric material may have at least two stable polarization states, it may be used to shift a threshold voltage of a field-effect transistor in a non-volatile fashion; therefore, it may be used to turn the field-effect transistor into a non-volatile field-effect transistor based memory structure. A ferroelectric material may turn a ferroelectric capacitor structure into a non-volatile capacitor based memory structure, e.g. by controlling the amount of charge stored in the capacitor structure.

In various aspects, a memory cell may have at least two distinct (memory) states associated therewith, for example with two distinct electrical conductivities or two distinct amounts of stored charge that may be determined to determine in which of the at least two distinct states the memory cell is residing in. In various aspects, a memory state the memory cell is residing may be a “programmed state” or an “erased state”. As an example, the programmed state may be an electrically conducting state or a state with positive stored charge (e.g., associated with a logic “1”) and the erased state may be an electrically non-conducting state or a state with negative stored charge (e.g., associated with a logic “0”). However, the definition of programmed state and erased state may be selected arbitrarily.

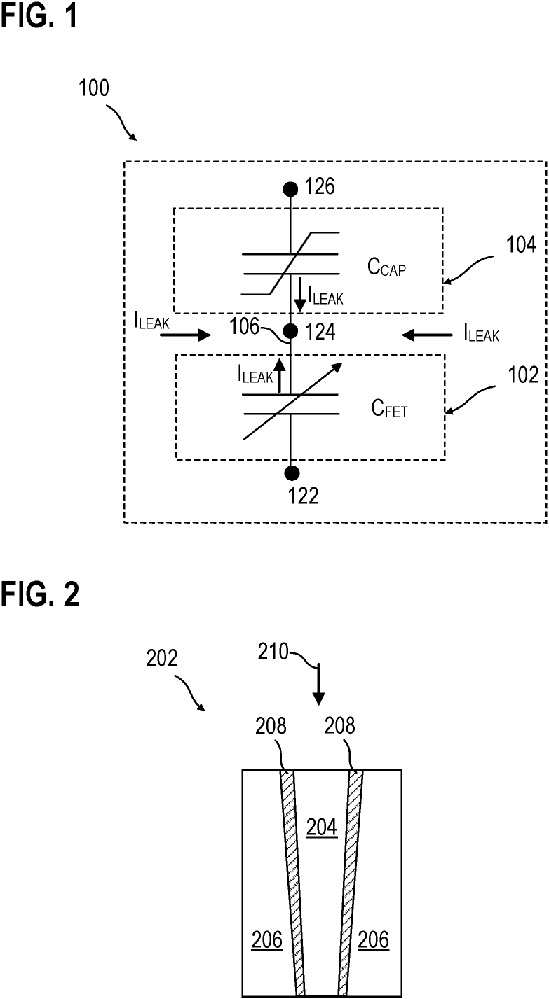

FIG. 1 shows schematically a circuit equivalent of a memory cell 100 including a field-effect transistor (FET) structure 102 and a capacitive (CAP) memory structure 104, according to various aspects. In some aspects, the memory cell 100 may be non-volatile memory cell.

The memory cell 100 may include an electrically conductive connection 106 (e.g., an ohmic connection) coupling the field-effect transistor structure 102 and the capacitive memory structure 104 with one another. In some aspects, the field-effect transistor structure 102 and the capacitive memory structure 104 may be coupled to one another such that a capacitive voltage divider is provided (in other words, such that the field-effect transistor structure 102 and the capacitive memory structure 104 form a capacitive voltage divider).

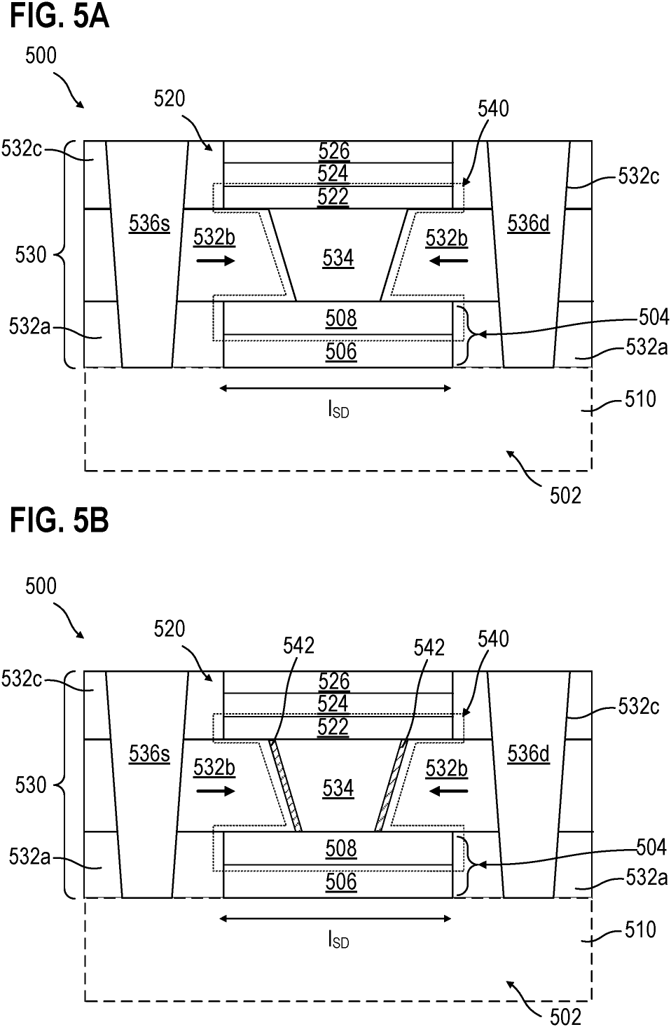

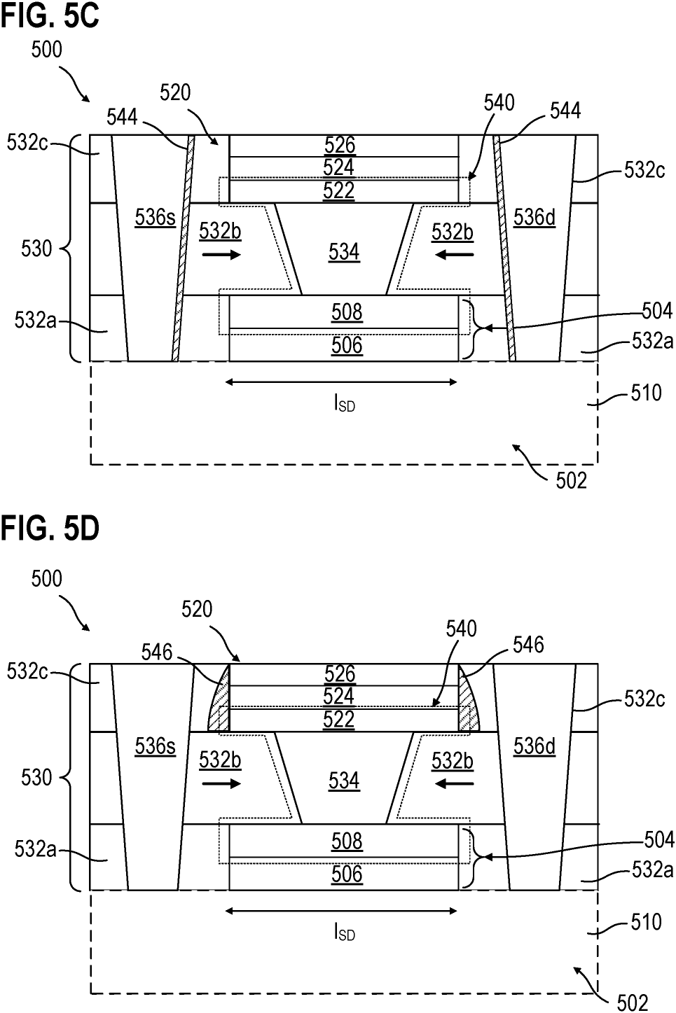

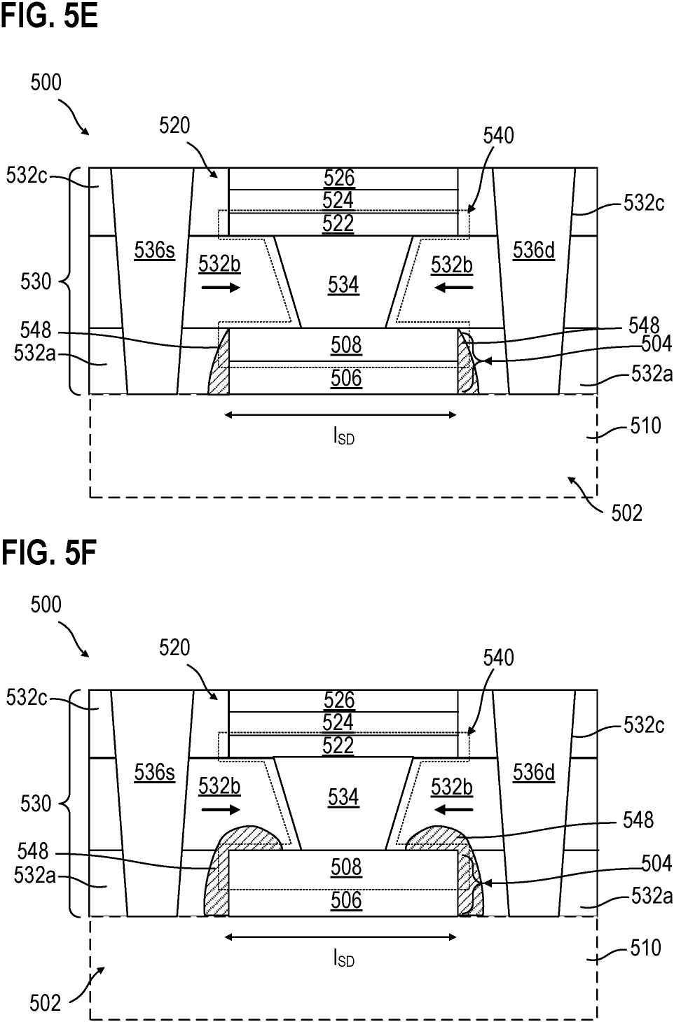

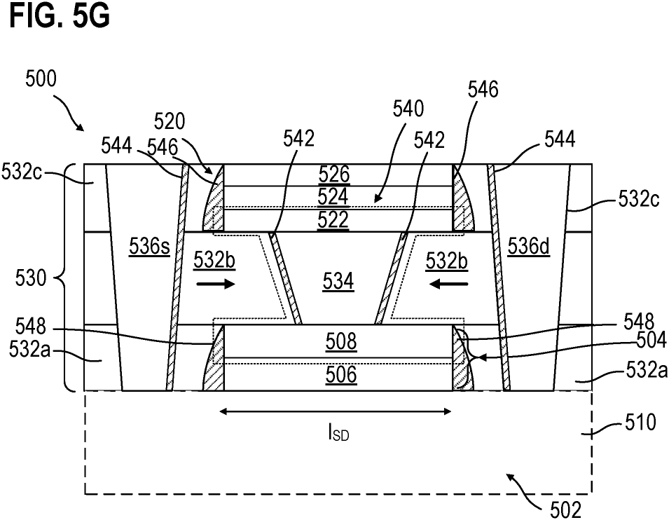

In some aspects, the electrically conductive connection 106 may be a connection structure electrically conductively connecting a gate electrode of the field-effect transistor structure 102 and a first electrode (e.g., a bottom electrode) of the capacitive memory structure 104 with one another (see for example FIG. 5A to FIG. 5G). In some aspects, the electrically conductive connection 106 between the field-effect transistor structure 102 and the capacitive memory structure 104 may include one or more metallization structures disposed over the field-effect transistor structure 102. Exemplary realizations of the memory cell 100 are described in further detail below, for example with reference to FIG. 5A to FIG. 5G.

A channel or bulk node of the field-effect transistor structure 102 may provide or may be connected to a first node 122, an electrode (e.g., a top electrode) of the capacitive memory structure 104 may provide or may be connected to a second node 126 and an intermediate conductive portion (e.g., an electrode, a layer, etc.) may provide a floating intermediate node 124. In some aspects, the electrically conductive connection 106 may be electrically floating, e.g. the floating node 124 may be present in the circuit due to the electrically conductive connection 106 between the field-effect transistor structure 102 and the capacitive memory structure 104 being electrically floating.

The field-effect transistor structure 102 may have a first capacitance C_{FET} associated therewith and the capacitive memory structure 104 may have a second capacitance C_{CAP} associated therewith. The capacitive voltage divider formed by the field-effect transistor structure 104 and the capacitive memory structure 104 may allow adapting the capacitances C_{FET}, C_{CAP} of the respective capacitors to allow an efficient programming of the capacitive memory structure 102. The overall voltage required for switching the memory cell 100 from one memory state into another memory state (e.g. from a high threshold voltage state to a low threshold voltage state, as described below), may become less in case the voltage distribution across the field-effect transistor structure 102 and the capacitive memory structure 104 is adapted such that more of the applied gate voltage drops across a functional layer of the capacitive memory structure 104 (e.g., across a remanent-polarizable layer, such as a ferroelectric layer) than across a gate isolation of the field-effect transistor structure 102. The overall write voltage may thus be reduced by adapting the capacitive voltage divider.

In some aspects, a capacitance that is associated with a field-effect transistor structure may not be constant, e.g., may be a function of the voltage that is applied. However, a so-called “dielectric” capacitance may be associated with the field-effect transistor structure that is substantially constant and defines a maximal capacitance of the field-effect transistor structure. The dielectric capacitance of a field-effect transistor structure may be dominant in the case that the channel of the field-effect transistor structure is conductive, e.g., for strong accumulation and for strong inversion, and, otherwise, the capacitance of the field-effect transistor structure may be less than the maximal capacitance. In some aspects, a capacitance that is associated with a capacitive memory structure may not be constant, e.g., may be a function of the voltage that is applied and/or a function of a polarization of the material included in the capacitive memory structure. However, a so-called “dielectric” capacitance may be associated with the capacitive memory structure that is substantially constant and defines a minimal capacitance of the capacitive memory structure. The capacitance of a capacitive memory structure may be greater than the minimal capacitance in the case that the polarization of a remanent-polarizable layer that is included in the capacitive memory structure is polarized and/or switched by an external electrical field.

In some aspects, a functional layer of the capacitive memory structure 104 may be a remanent-polarizable layer. By increasing the capacitance C_{FET} of the field-effect transistor structure 102, the depolarization field E_{Dep} of the remanent-polarizable layer may be reduced. The depolarization field E_{Dep} may be detrimental to data retention since, depending on its magnitude, it may depolarize the remanent-polarizable layer. However, the magnitude may be reduced by increasing the capacitance ratio C_{FET}/C_{CAP}. Accordingly, in case the capacitance C_{FET} of the field-effect transistor structure 102 is increased, the depolarization field is reduced. This in turn improves the data retention of the memory cell 100. In some aspects, the field-effect transistor structure 102 may be configured such that a ratio of the (first) capacitance C_{FET} of the field-effect transistor structure 102 to the (second) capacitance C_{CAP} of the capacitive memory structure 104 may be in the range from about 1 to about 100, for example in the range from about 1 to about 25, or from about 2 to about 25, for example in the range from about 1 to about 16, for example the ratio of the first capacitance C_{FET} to the second capacitance C_{CAP} may be 4. The ratio of the first capacitance C_{FET} to the second capacitance C_{CAP} may be adapted, as an example, by adapting a ratio of a surface area of the field-effect transistor structure 102 to a surface area of the capacitive memory structure 104. The ratio of the first capacitance C_{FET} to the second capacitance C_{CAP} may be adapted, as another example, by adapting a gate isolation of the field-effect transistor structure 102.

In the case that the capacitance C_{FET} of the field-effect transistor structure 102 is increased, a higher fraction of the voltage applied to the series connection may drop across the capacitive memory structure 104. Accordingly, the electric field generated across the gate isolation of the field-effect transistor structure 102 underneath the capacitive memory structure 104 reduces because the voltage drop across this region is reduced. This leads to a reduced interfacial field stress, which may lead to a reduced wear out of the interface due to, for example, charge injection. Therefore, the reduced electric field generated across the gate isolation may lead to improved endurance characteristics of the memory cell 100, that is, to an increased amount of possible polarization reversals (e.g., in case the functional layer is a remanent-polarizable layer) until the memory cell 100 may lose its memory properties.

Coupling the field-effect transistor structure 102 and the capacitive memory structure 104 with one another, as described above, may therefore provide the possibility of tuning the respective capacitances to ensure more reliable data retention and to allow an overall reduction of the write voltage, thus increasing a lifetime of the memory cell 100. However, a substantive accumulation of charges in the floating node 124 (e.g., in the electrically floating elements, for example in the electrically conductive connection, in the first electrode of the capacitive memory structure 104, and in the gate electrode of the field-effect transistor structure 102) may not be desired for an operation of the memory cell 100. The floating node 124 may be, in some aspects, prone to charging from leakage currents present in the memory cell 100, and may not be easily discharged in view of its floating nature. There may be leakage currents (e.g., tunneling currents) flowing from various directions towards the floating node 124, as indicated in FIG. 1. The accumulation of charges in the floating node induced by the leakage currents over relatively long period of times (e.g., weeks, months, or years) may negatively affect the operation of the memory cell 100. As an example, the charging of the floating node 124 may lead to an unpredictable behavior of the memory cell 100 during a readout operation or a write operation, e.g. due to an influence of the charged floating node 124 on the electrical potential provided at the memory cell 100.

Various aspects may be based on providing a memory cell in which leakage current-induced charging of a floating node (e.g., charging of the electrically floating elements induced by a leakage current) may be reduced or substantially eliminated. The memory cell described herein may be configured such that the electrically floating elements are protected (e.g., in one or more directions) to substantially prevent leakage current(s) from charging the floating node. This in turn may increase the reliability and the reproducibility of an operation of the memory cell, e.g. of a readout operation and/or write operation. In the following, various configurations, e.g. one or more (additional) electrically insulating structures, for the protecting of the floating node are described, which may be implemented individually or in combination with one another depending on a configuration of the memory cell. The number or the disposition of the electrically insulating structures in the memory cell may be selected, for example, depending on an expected presence or magnitude of leakage currents in the memory cell.

The protection of the electrically floating elements is described herein in relation to a memory cell, e.g. a memory cell configured as the memory cell 100 described in relation to FIG. 1. It is however understood that the measures described herein may be applicable in any type of device in which it may be desired to protect a floating node, e.g. to prevent a leakage current that charges the floating node. The measures described herein may be applicable in any type of memory cell in which a portion of the memory cell may be negatively affected by leakage currents flowing thereto.

The protection of the floating node may also provide the possibility of down-scaling the (lateral) dimensions of the memory cell, e.g. for its use at a 28 nm technology node. In case the dimensions of the memory cell (e.g., of the field-effect transistor structure and/or of the capacitive memory structure) are reduced, leakage currents may more easily occur, e.g. due to tunneling. The protection of the floating node may allow down-scaling the dimensions of the memory cell without incurring in a deterioration of the operations of the memory cell.

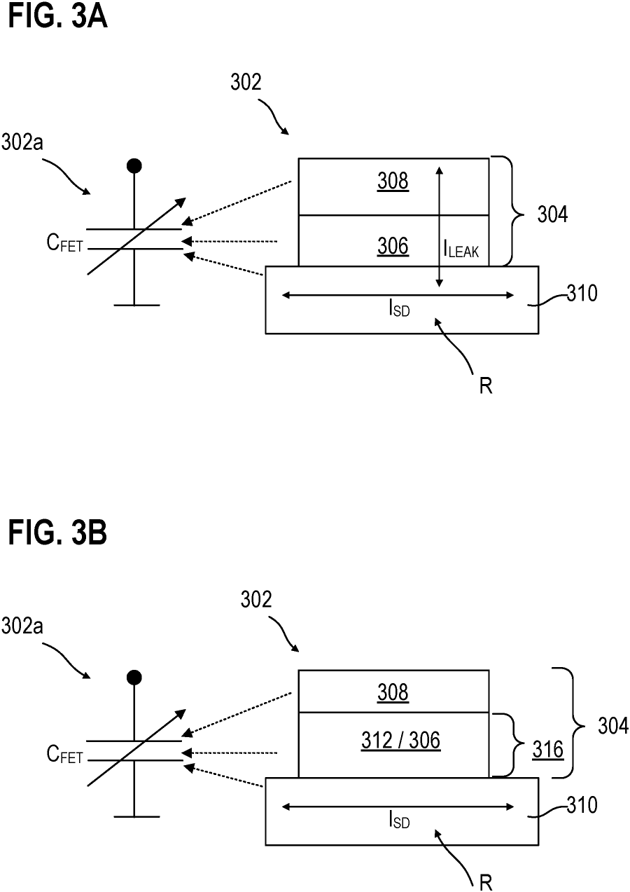

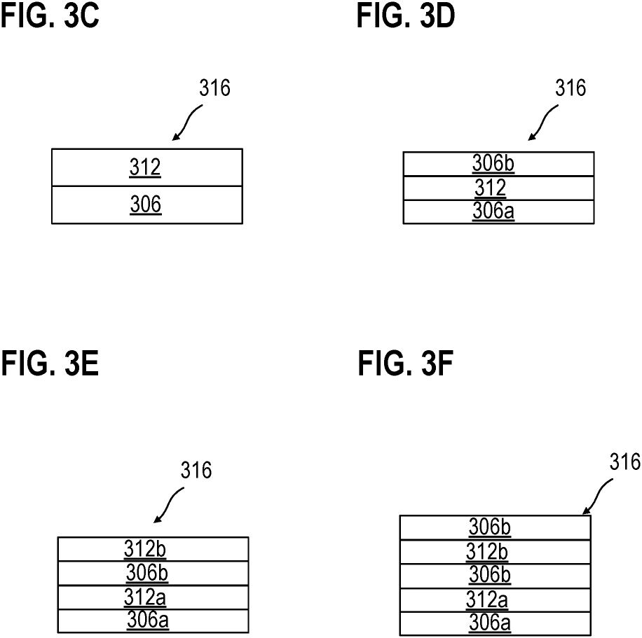

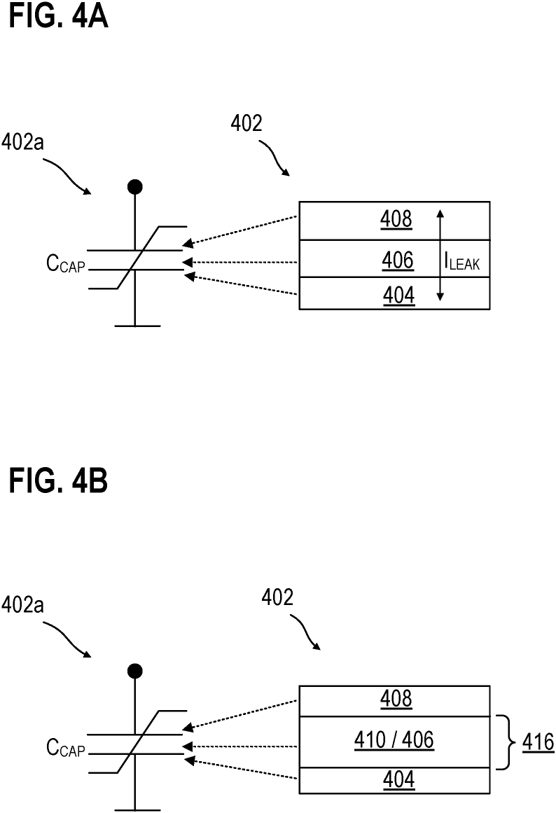

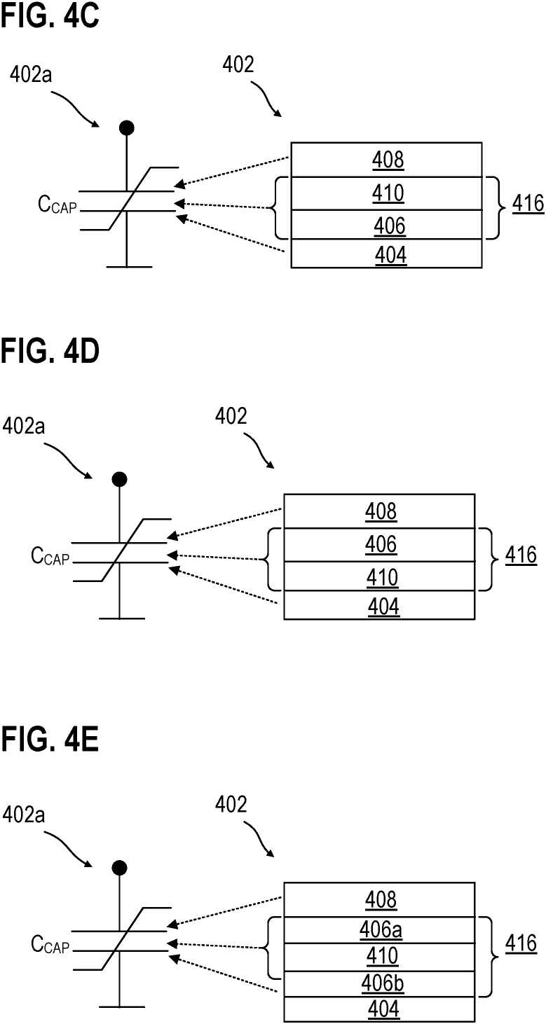

In the following, e.g. in the FIG. 3A and FIG. 3B and in the FIG. 5A to FIG. 5G, exemplary realizations of a field-effect transistor structure that may be part of a memory cell (e.g., of the memory cell 100) may be illustrated exemplarily as a planar gate stack, however it is understood that the planar configuration is an example, and other field-effect transistor designs may include a gate structure with a non-planar shape, for example a trench gate transistor design, a vertical field-effect transistor design, a fin field-effect transistor (FinFET) design (e.g., including a semiconductor portion having the shape of a vertical fin), a nanosheet or nanowire field-effect transistor design (e.g., including a semiconductor portion having the shape of a nanosheet or nanowire), as examples. Analogously, in the following, e.g. in the FIG. 4A and FIG. 4B and in the FIG. 5A to FIG. 5G, exemplary realizations of a capacitive memory structure that may be part of a memory cell (e.g., of the memory cell 100) may be illustrated exemplarily as a planar capacitor structure, however it is understood that the planar configuration is an example, and other capacitive memory structure designs may include a capacitor structure with a non-planar shape.

FIG. 2 shows schematically a metallization structure 202 including a contact structure 204, according to various aspects. The metallization structure 202 may be for use in a memory cell (e.g., in the memory cell 100). In some aspects, the metallization structure 202 may be an exemplary realization of an electrically conductive connection between a field-effect transistor structure (e.g., the field-effect transistor structure 102) and a capacitive memory structure (e.g., the capacitive memory structure 104), e.g. the contact structure 204 may be an exemplary realization of a connection structure (see for example FIG. 5A to FIG. 5G). In some aspects, the metallization structure 202 may be an exemplary realization of a structure for allowing a control of a memory cell, e.g. for contacting (e.g., accessing) a field-effect contact structure in a memory cell. In some aspects, the contact structure 204 may be an exemplary realization of a source/drain contact structure (see for example FIG. 5A to FIG. 5G).

The contact structure 204 may be embedded in (e.g., laterally surrounded by) an insulator layer 206 (in other words, an electrically insulating layer). The contact structure 204 may include an electrically conductive material, for example the contact structure 204 may include a metal (e.g., at least one metal layer), such as tungsten (W) or cobalt (Co), as examples, or any other conductive material (e.g., a metal alloy, a degenerate semiconductor, a polysilicon layer, etc.).

The insulator layer 206 may include an electrically insulating material, for example a dielectric material, e.g., silicon oxide (SiO₂), silicon nitride (SiNₓ), or any other electrically insulating material. The insulator layer 206 is illustrated in FIG. 2 as a single layer, however in some aspects the insulator layer 206 may be understood as a plurality of insulator layers (as described in relation to FIG. 5A to FIG. 5G).

In some aspects, the metallization structure 202 may extend through one or more metal levels, e.g. in addition or in alternative to extending through an insulator layer (e.g., through the insulator layer 204), as described in further detail below, for example in relation to FIG. 5A to FIG. 5G. By way of example, the metallization structure 202 may extend from a contact level to a fourth metal level, e.g. in a memory cell, as described in further detail below.

The metallization structure 202 may be configured to prevent charging of a floating node induced by a leakage current. In some aspects, the metallization structure 202 may include one or more (further) electrically insulating layers 208 (also referred to herein as one or more contact charge-prevention layers 208) at least partially surrounding a sidewall of the contact structure 204. In the following, reference is made to a contact charge-prevention layer 208, shown in FIG. 2, it is however intended that the contact charge-prevention layer 208 may be understood as one or more contact charge-prevention layers 208.

The contact charge-prevention layer 208 may at least partially cover a sidewall of the contact structure 204 (e.g., may cover a sidewall of an opening formed in the insulator layer 206, into which opening the contact structure 204 is formed). In some aspects, the contact charge-prevention layer 208 may partially surround the sidewall of the contact structure 204, e.g. the contact charge-prevention layer 208 may be disposed on a portion but not all of the sidewall of the contact structure 204. In some aspects, the contact charge-prevention layer 208 may completely laterally surround (e.g., completely laterally cover) the sidewall of the contact structure 204. In some aspects, the contact charge-prevention layer 208 may be in direct physical contact with the sidewall of the contact structure 204. Illustratively, the contact charge-prevention layer 208 may be interposed between the contact structure 204 and the insulator layer 206, e.g. the contact charge-prevention layer 208 may be in direct physical contact with the insulator layer 206 and with the contact structure 204. The contact charge-prevention layer 208 may be understood as an insulation liner being in direct physical contact with the insulator layer(s) 206.

In some aspects, the contact charge-prevention layer 208 may be conformally deposited on the sidewall of the contact structure 204 (e.g., on the sidewall of an opening in the insulator layer 206 in which opening the contact structure 204 is formed). In some aspects, a first interface may be present between the contact charge-prevention layer 208 and the insulator layer 206, and a second interface may be present between the contact charge-prevention layer 208 and the contact structure 204. The contact charge-prevention layer 208 may have a (total and/or individual) thickness less than 20 nm, for example less than 10 nm or less than 5 nm.

In some aspects, the contact charge-prevention layer 208 may include an electrically insulating material, for example a dielectric material such as an oxide or a nitride material (e.g., Al₂O₃, AlN, AlOₓN_{y} or SiO₂ SiN, SIOₓN_{y}).

In some aspects, the contact charge-prevention layer 208 may include a material having a (relatively) low dielectric constant (also referred to as relative permittivity). In some aspects, the material of the contact charge-prevention layer 208 may have a dielectric constant in the range from about 3 to about 15, for example a dielectric constant equal to or less than 15 or equal to or less than 4. In some aspects, the contact charge-prevention layer 208 may include (in some aspects, may be made of) a low-k dielectric material. In some aspects, the material of the contact charge-prevention layer 208 may include one of the materials described below in relation to a first gate isolation layer 306a in FIG. 3A to FIG. 3F.

In some aspects, the contact charge-prevention layer 208 may include a material having a (relatively) high dielectric constant. In some aspects, the material of the contact charge-prevention layer 208 may have a dielectric constant greater than 15 (in some aspects, greater than 4). In some aspects, the contact charge-prevention layer 208 may include (in some aspects, may be made of) a high-k dielectric material. In some aspects, the material of the contact charge-prevention layer 208 may include one of the materials described below in relation to a second gate isolation layer 306b in FIG. 3A to FIG. 3F.

In some aspects, a sidewall of the contact structure 204 may be understood as a single (continuous) portion, e.g. a single portion facing away from the contact structure 204 (and facing the insulator layer 206). This may be the case, for example, in case the contact structure 204 has a circular shape (e.g., a circular cross section as seen from the top, e.g. as seen looking at the contact structure 204 in the direction pointed by the arrow 210 in FIG. 2). In some aspects, a sidewall of the contact structure 204 may be understood as (e.g., may include) a plurality of portions, each facing away from the contact structure 204 (and facing the insulator layer 206). This may be the case, for example, in case the contact structure 204 has a polygonal shape (e.g., a polygonal cross section as seen from the top). Illustratively, the sidewall may include each side (e.g., each face) of the polygon.

The contact charge-prevention layer 208 may be configured to prevent leakage current-induced charging of electrically floating elements in a memory cell, as described in further detail below, for example in relation to FIG. 5A to FIG. 5G. In some aspects, e.g. in case the contact structure 204 is a connection structure, the contact charge-prevention layer 208 may be provided to prevent a leakage current to flow into the contact structure 204. In some aspects, e.g. in case the contact structure 204 is a source/drain contact structure, the contact charge-prevention layer 208 may be provided to prevent a leakage current to flow away from the contact structure 204 (e.g., may be provided to prevent flow of charges away from the contact structure 204).

In some aspects, the metallization structure 202 may include one or more charge trapping layers (not shown in FIG. 2) configured to trap charges. The one or more charge trapping layers may at least partially surround the sidewall of the contact structure 204. The one or more charge trapping layers may be in addition (or in alternative) to the contact charge-prevention layer 208. The one or more charge trapping layers may include a combination of electrically insulating and/or electrically conductive materials, e.g. the one or more charge trapping layers may include a plurality of layers, each layer including an electrically insulating or an electrically conductive material. In some aspects, the one or more charge trapping layers may include an electrically conductive layer sandwiched between two electrically insulating layers (e.g., a metal layer disposed between two dielectric layers). The one or more charge trapping layers may be provided, for example, in case the contact structure 204 is a source/drain contact structure, described in further detail below. The one or more charge trapping layers may contribute to the reduction of charging of the floating node induced by leakage currents.

FIG. 3A and FIG. 3B each shows schematically a field-effect transistor structure 302, according to various aspects. In some aspects, the field-effect transistor structure 302 may be for use in a memory cell (e.g., in the memory cell 100), e.g. the field-effect transistor structure 302 may be an exemplary realization of the field-effect transistor structure 102 described in relation to FIG. 1.

The field-effect transistor structure 302 may include a gate structure 304. The gate structure 304 may include a gate isolation 306 and a gate electrode 308. The gate structure 304 may define a channel region 310, e.g., provided in a semiconductor layer (e.g., in a semiconductor die). The gate structure 304 may allow for a control of an electrical behavior of the channel region 310. The gate structure 304 may, for example, be used to control (e.g., to allow or prevent) a current flow in the channel region 310. In other words, the gate structure 304 may, for example, allow to control (e.g., to allow or prevent) a source/drain current, I_{SD}, from a first source/drain region of the field-effect transistor structure 302 to a second source/drain region of the field-effect transistor structure 302 (the source/drain regions may be provided in or adjacent to the channel but are not shown in FIG. 3A or FIG. 3B). The channel region 310 and the source/drain regions may be formed, e.g., via doping one or more semiconductor materials or by the use of intrinsically doped semiconductor materials, within a layer and/or over a layer. In some aspects, the gate structure 304 may allow to control (e.g., to increase or reduce) an electrical resistance, R, of the channel region 310 and, accordingly, to control the amount of current that may flow through the channel region 310. With respect to the operation of the field-effect transistor structure 302, a voltage (illustratively an electrical potential) may be provided at (e.g., supplied to) the gate electrode 308 to control the current flow, I_{SD}, in the channel region 310, the current flow, I_{SD}, in the channel region 310 being caused by voltages supplied via the source/drain regions.

In various aspects, the semiconductor layer may be made of or may include silicon. However, other semiconductor materials of various types may be used in a similar way, e.g. germanium, Group III to V (e.g. SiC), or other types, including for example carbon nanotubes, organic materials (e.g., organic polymers), etc. In various aspects, the semiconductor layer may be a wafer made of silicon (e.g. p-type doped or n-type doped). In other aspects, the semiconductor layer may be a silicon on insulator (SOI) wafer. In other aspects, the semiconductor layer may be provided by a semiconductor structure, e.g., by one or more semiconductor fins, one or more semiconductor nanosheets, one or more semiconductor nanowires, etc., disposed at a carrier, as described above.

As illustrated by the circuit equivalent 302a shown in FIG. 3A and FIG. 3B, the channel region 310, the gate isolation 306, and the gate electrode 308 may have a capacitance C_{FET} associated therewith, originating from the more or less conductive regions (the channel region 310 and the gate electrode 308) separated from one another by the gate isolation 306. Illustratively, in a planar configuration, the channel region 310 may be considered as a first capacitor electrode, the gate electrode 308 as a second capacitor electrode, and the gate isolation 306 as a dielectric medium between the two capacitor electrodes. The capacitance C_{FET} of the field-effect transistor structure 302 may be calculated using equations known in the art in case of a planar structure as well as in case of a non-planar structure or modified variant of a planar structure of the field-effect transistor structure 302.

The gate electrode 308 may include an electrically conductive material, for example, polysilicon, aluminum, etc. In some aspects, the gate electrode 308 may include any suitable electrically conductive material, e.g., a metal, a metal alloy, a degenerate semiconductor (in other words a semiconductor material having such a high level of doping that the material acts like a metal and not anymore as a semiconductor). The gate electrode 308 may include one or more electrically conductive portions, layers, etc. The gate electrode 308 may include an electrically conductive material, e.g., a metal (for example aluminum), a metal alloy, a degenerate semiconductor, polysilicon, etc. In various aspects, the gate electrode 308 may include, for example, one or more metal layers (also referred to as a metal gate), one or more polysilicon layers (also referred to as poly-Si-gate), etc. A metal gate may include, for example, at least one work-function adaption metal layer disposed over the gate isolation 306 and an additional metal layer disposed over the work-function adaption metal layer. A poly-Si-gate may be, for example, p-type doped or n-type doped.

According to various aspects, the gate isolation 306 may be configured to provide an electrical separation of the gate electrode 308 from the channel region 310 and further to influence the channel region 310 via an electric field generated by the gate electrode 308. The gate isolation 306 may include (in some aspects may consist of) an electrically insulating material, e.g. a dielectric material (e.g., a low-k dielectric material, a high-k dielectric material, as examples). In some aspects, the gate isolation 306 may include a plurality of gate isolation layers, e.g., a first gate isolation layer (e.g., a first dielectric layer including a first dielectric material, see for example the layer 306a in FIG. 3D to FIG. 3F) and a second gate isolation layer (e.g., a second dielectric layer including a second dielectric material distinct from first dielectric material, see for example the layer 306b in FIG. 3D to FIG. 3F). The first gate isolation layer 306a may include (in some aspects, may be made of) a (first) material having first dielectric constant, e.g. a (relatively) low dielectric constant (also referred to as relative permittivity). In some aspects the material of the first gate isolation layer 306a may have a (first) dielectric constant less than a (second) dielectric constant of a material of a second gate isolation layer 306b (for example a difference between the second dielectric constant and the first dielectric constant may be at least three, or at least five). In some aspects, the material of the first gate isolation layer 306a may have a dielectric constant in the range from about 3 to about 15, for example a dielectric constant equal to or less than 15 or equal to or less than 4.

In some aspects, the first gate isolation layer 306a may include (in some aspects, may be made of) low-k dielectric material. The first gate isolation layer 306a may be referred to herein, in some aspects, as low-k material layer. A low-k (LK) dielectric material as described herein may include any suitable insulator material that has a dielectric constant less than the dielectric constant of silicon dioxide (SiO2), e.g. with a relative permittivity εᵣ being equal to or less than 3.9 (in some aspects, equal to or less than 4). In some aspects, the first gate isolation layer 306a may include a material having dielectric constant greater than 4, e.g. a dielectric constant up to 15, for example for forming on the first gate isolation layer 306a a further (second) gate isolation layer including a material with high dielectric constant. In some aspects, the material of the first gate isolation layer 306a may include silicon dioxide and/or its doped or modified variants (e.g., doped with fluorine or carbon). In some aspects the material of the first gate isolation layer 306a may include at least one of the following: silicon, silicon oxide, silicon nitride, silicon oxynitride, aluminum, aluminum oxide, aluminum nitride, aluminum oxynitride. In some aspects, silicon dioxide may be considered as a low-k material (despite having an “intermediate” dielectric constant), in other words, silicon dioxide in the context of the present application may be understood as a low-k material (e.g., a silicon oxide layer may, in some aspects, be understood as a low-k material layer). It is understood that the materials mentioned herein may represent possible examples, and that any material having the desired properties and applicable in processing of field-effect transistor structures may be used, for example as a material of the first gate isolation layer 306a. In some aspects, the first gate isolation layer 306a may be referred to as buffer layer.

According to various aspects, the second gate isolation layer 306b may include (in some aspects, may be made of) a (second) material having second dielectric constant, e.g. a (relatively) high dielectric constant. In some aspects the material of the second gate isolation layer 306b may have a (second) dielectric constant greater than the (first) dielectric constant of the material of the first gate isolation layer 306a. In some aspects, the material of the second gate isolation layer 306b may have a dielectric constant greater than 4 (in some aspects, greater than 10, greater than 15, or greater than 30, in some aspects 16 or 35). In some aspects, the second gate isolation layer 306b may include (in some aspects, may be made of) a high-k dielectric material. The second gate isolation layer 306b may be referred to, in some aspects, as high-k material layer. A high-k (HK) dielectric material as described herein may include any suitable insulator material that has a relative permittivity greater than the relative permittivity of silicon dioxide, e.g. with a relative permittivity εᵣ being greater than 3.9 (in some aspects, greater than 4). In some aspects, the material of the second gate isolation layer 306b may include, for example, hafnium oxide (HfO2), zirconium oxide (ZrO2), lanthanum oxide (La₂O3), aluminum oxide (Al₂O₃), and their doped/modified variants (e.g. doped with silicon). In some aspects, the material of the second gate isolation layer 306b may include at least one of the following: hafnium, zirconium, lanthanum, strontium, calcium, hafnium oxide, zirconium oxide, silicon doped hafnium oxide, lanthanum oxide, strontium titanate, calcium titanate. In some aspects, the material of the second gate isolation layer 306b may include at least one of the following: a transition metal oxide (e.g., a doped, alloyed, substituted and/or undoped transition metal oxide), a perovskite (e.g., a doped, alloyed, substituted and/or undoped transition metal perovskite). It is understood that the materials mentioned herein may represent possible examples, and that any material having the desired properties and applicable in processing of field-effect transistor structures may be used, for example as a material of the second gate isolation layer 306b.

Illustratively, in some aspects, the field-effect transistor structure 302 may include a first gate isolation layer 306a having a first dielectric constant and a first chemical composition, and the field-effect transistor structure 302 may include a second gate isolation layer 306b having a second dielectric constant and a second chemical composition. The first dielectric constant may be different from (in some aspects, less than) the second dielectric constant. Additionally or alternatively, the first chemical composition may be different from the second chemical composition (e.g., e.g., different doping, different content of the participating elements, or the like). The first gate isolation layer 306a and the second gate isolation layer 306b may be disposed between the gate electrode 308 and the channel region 310.

A gate leakage current, I_{LEAK}, may be present in the field-effect transistor structure 302 resulting in a charge transfer between the gate electrode 308 and the channel region 310, e.g., due to the dimensions of the gate isolation 306, which may cause a tunnel current and/or a leakage current through grain boundaries or other imperfections in the crystallographic structure of the material(s) of the gate isolation 306.

In various aspects, the field-effect transistor structure 302 may be configured to reduce or prevent a leakage current I_{LEAK} from charging electrically floating elements in a memory cell. The field-effect transistor structure 302 may include one or more (additional) electrically insulating layer 312 (also referred to herein as one or more gate electrode charge-prevention layers 312), see for example FIG. 3B to FIG. 3F, configured to prevent leakage current-induced charging of electrically floating elements in a memory cell (e.g., charging of an electrically conductive connection coupling the field-effect transistor structure 302 and a capacitive memory structure with one another). In the following, reference is made to a gate electrode charge-prevention layer 312, shown in FIG. 3B to FIG. 3F, it is however intended that the gate electrode charge-prevention layer 312 may be understood as one or more gate electrode charge-prevention layers 312.

The gate electrode charge-prevention layer 312 may be disposed in various positions within the field-effect transistor structure 302, e.g. disposed between the channel 310 and the gate electrode 308 (for example, integrated into a usual gate isolation 306 and/or disposed over and/or under a usual gate isolation 306). Illustratively, the gate isolation 306 may be modified by including at least one additional layer that is referred to herein as gate electrode charge-prevention layer 312, wherein, in the following, such a “modified” gate isolation 316 (see FIG. 3B to FIG. 3F) is described in more detail.

In various aspects, the gate electrode charge-prevention layer 312 may be an example of additional electrically insulating structure of a memory cell. A memory cell (e.g., the memory cell 100) may include a field-effect transistor structure including a gate electrode charge-prevention layer. Illustratively, the gate electrode charge-prevention layer 312 may provide a containment of the gate leakage current I_{LEAK} such that charging of electrically floating elements induced by the gate leakage current I_{LEAK} may be substantially prevented.

The gate electrode charge-prevention layer 312 may include an electrically insulating material, for example a dielectric material such as an oxide or a nitride material (e.g., Al₂O₃, AlN, AlOₓN_{y} or SiO₂ SiN, SIOₓN_{y}). In some aspects, the gate electrode charge-prevention layer 312 may include one of the materials described above in relation to the first gate isolation layer 306a, e.g. a low-k dielectric material. In some aspects, the gate electrode charge-prevention layer 312 may include e.g. one of the materials described above in relation to the second gate isolation layer 306b, e.g. a high-k dielectric material. In some aspects, the gate electrode charge-prevention layer 312 may have a (total and/or individual) thickness in the range from about 0.5 nm to about 1.5 nm, for example from about 1 nm to about 3 nm.

The gate electrode charge-prevention layer 312 may be understood as part of the gate isolation 316, e.g. the gate electrode charge-prevention layer 312 may be a further layer with respect to the gate isolation, however, the main aspect to include such gate electrode charge-prevention layer 312 may be the leakage current prevention and not, as usual, the switching of the transistor structure 302. In some aspects, the gate electrode charge-prevention layer 312 may include a different material with respect to the gate isolation 316 (e.g., with respect to the first gate isolation layer 306a and/or to the second gate isolation layer 306b), e.g. a material having a different dielectric constant and/or a different chemical composition. In some aspects, the gate electrode charge-prevention layer 312 may include a same material as the gate isolation 316 (e.g., as the first gate isolation layer 306a or as the second gate isolation layer 306b), e.g. a material having a same dielectric constant and/or a same chemical composition.

In case, only as an example, two adjacent layers of the gate isolation 316 may be formed of the same material, e.g., a first gate isolation layer 306a (e.g., a low-k dielectric layer) and the gate electrode charge-prevention layer 312, see. FIG. 3D, the layers may be formed by distinct deposition processes, wherein, as a result of the used distinct deposition processes, an interface region or interface layer may be present (e.g., including dislocations, defects, or other microstructural features) between the two adj acent layers indicating the presence of two distinct layers.

FIG. 3C to FIG. 3F show schematically a (modified) gate isolation 316, according to various aspects. Illustratively, the FIG. 3C to FIG. 3F show various exemplary dispositions of the gate electrode charge-prevention layer 312 (in some aspects, of a plurality of gate electrode charge-prevention layers 312) with respect to a (usual) gate isolation 306. In some aspects, the field-effect transistor structure 302 may include a plurality of gate electrode charge-prevention layers 312 (e.g., including the same electrically insulating material or different electrically insulating materials), for example disposed in different positions within the gate isolation 316 (see for example FIG. 3E and FIG. 3F).

As illustrated in FIG. 3C, the gate electrode charge-prevention layer 312 may be disposed over the (usual) gate isolation 306, e.g. between the gate isolation 306 and the gate electrode 308. The gate electrode charge-prevention layer 312 may be in direct physical contact with the gate isolation 306 and the gate electrode 308.

As illustrated in FIG. 3D, the gate electrode charge-prevention layer 312 may be disposed between a first gate isolation layer 306a (e.g., a low-k dielectric layer, as described above) and a second gate isolation layer 306b (e.g., a high-k dielectric layer, as described above), e.g. may be disposed as an interlayer within the gate isolation 306. A first interface may be present between the gate electrode charge-prevention layer 312 and the first gate isolation layer 306a, and a second interface may be present between the gate electrode charge-prevention layer 312 and the second gate isolation layer 306b.

As illustrated in FIG. 3E, a first gate electrode charge-prevention layer 312a may be disposed between the first gate isolation layer 306a and the second gate isolation layer 306b, and a second gate electrode charge-prevention layer 312b may be disposed over the second gate isolation layer 306b (e.g., between the second gate isolation layer 306b and the gate electrode 308). As illustrated in FIG. 3F, a further second gate isolation layer 306b may be disposed over the second gate electrode charge-prevention layer 312b, e.g. the second gate electrode charge-prevention layer 312b may be between a first portion and a second portion of the second gate isolation layer 306b.

It is understood that other arrangements of the gate electrode charge-prevention layer 312 may be possible. As an example, the gate electrode charge-prevention layer 312 may be disposed below the gate isolation 306 (e.g., between the gate isolation 306 and the channel region 310). As another example, the gate electrode charge-prevention layer 312 may be disposed over the gate electrode 308 or within the gate electrode 308 (e.g., between a first portion and a second portion of the gate electrode 308). As a further example, a first gate electrode charge-prevention layer may be disposed between the first gate isolation layer 306a and the second gate isolation layer 306b, and a second gate electrode charge-prevention layer may be disposed underneath the first gate isolation layer 306a (e.g., between the first gate isolation layer 306a and the channel region 310). A further first gate isolation layer 306a may be disposed over the second gate electrode charge-prevention layer, e.g. the second gate electrode charge-prevention layer may be between a first portion and a second portion of the first gate isolation layer 306a.

FIG. 4A to FIG. 4E each shows schematically a capacitive memory structure 402, according to various aspects. The capacitive memory structure 402 may be for use in a memory cell (e.g., in the memory cell 100), e.g. in some aspects the capacitive memory structure 402 may be an exemplary realization of the capacitive memory structure 104 described in relation to FIG. 1.

The capacitive memory structure 402 may include any type of planar or non-planar design with at least a first electrode 404, a second electrode 408 and at least one remanent-polarizable layer 406 disposed between the first electrode 404 and the second electrode 408, e.g. to provide memory functions.

As illustrated by the circuit equivalent 402a in FIG. 4A to FIG. 4E, the first electrode 404, the second electrode 408, and the at least one remanent-polarizable layer 406 may have a capacitance C_{CAP} associated therewith. In a planar configuration, the first electrode 404 of the capacitive memory structure 402 may be a first capacitor electrode, the second electrode 408 may be a second capacitor electrode, and the at least one remanent-polarizable layer 406 may be a dielectric medium between the first capacitor electrode and the second capacitor electrode. The capacitance C_{CAP} of the capacitive memory structure 402 may be calculated using equations known in the art in case of a planar structure as well as in case of a non-planar structure or modified variant of a planar structure of the capacitive memory structure 402.

The at least one remanent-polarizable layer 406 may include any type of remanent-polarizable and/or spontaneously-polarizable material, e.g., a ferroelectric material, an anti-ferroelectric material, an anti-ferroelectric-like material, etc. The at least one remanent-polarizable layer 406 may be the functional layer of the capacitive memory structure 402 to store, for example, an information via at least two remanent polarization states of the at least one remanent-polarizable layer 406. The programming of the capacitive memory structure 402 (illustratively the storage of information therein) may be carried out by providing an electric field between the first electrode 404 and the second electrode 406 (e.g., an electric potential difference between a first node and a second node associated with the first electrode 404 and the second electrode 408, respectively, as described in relation to FIG. 1) to thereby set or change the remanent polarization state of the at least one remanent-polarizable layer 406. As an example, a voltage may be provided between the top electrode 408 and the bulk region of a field-effect transistor structure coupled with the capacitive memory structure 402.

It is understood that a remanent-polarizable layer 406 is only an example of a possible functional layer of the capacitive memory structure 402, and any other functional layer whose state may be altered by an electric field provided across the capacitive memory structure 402 may be used.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a remanent polarization of a material, similar to ferromagnetism and anti-ferromagnetism used to describe remanent magnetization in magnetic materials.

According to various aspects, the residual polarization of the remanent-polarizable layer 406 may define the memory state a memory cell is residing in. The polarization state of the remanent-polarizable layer 406 may be switched by means of the capacitive memory structure 402. The polarization state of the remanent-polarizable layer 406 may also be read out by means of the capacitive memory structure 402. According to various aspects, a memory cell (e.g., the memory cell 100) including the capacitive memory structure 402 may reside in a first memory state in the case that the remanent-polarizable layer 406 is in a first polarization state, and the memory cell may reside in a second memory state in the case that the remanent-polarizable layer 406 is in a second polarization state (e.g., opposite to the first polarization state). As an example, the polarization state of the remanent-polarizable layer 406 may determine the amount of charge stored in the capacitive memory structure 402. The amount of charge stored in the capacitive memory structure 402 may be used to define a memory state of the memory cell. The threshold voltage of a field-effect transistor structure of the memory cell (e.g., the field-effect transistor structure 102) may be a function of the amount and/or polarity of charge stored in the capacitive memory structure 402, e.g. the threshold voltage may be a function of the polarization state of the remanent-polarizable layer. A first threshold voltage, e.g. a high threshold voltage V_{H}-th, may be associated with the first polarization state (e.g., with the first amount and/or polarity of stored charge), and a second threshold voltage, e.g. a low threshold voltage V_{L}-th, may be associated with the second polarization state (e.g., with the second amount and/or polarity of stored charge). Illustratively, the first memory state may be associated with the first threshold voltage, and the second memory state may be associated with the second threshold voltage.

According to various aspects, a ferroelectric material may be used as part of a capacitive memory structure of a memory cell (e.g., as part of the capacitive memory structure 104 of a memory cell 100, e.g. as part of the capacitive memory structure 402). A ferroelectric material may be an example of material of a remanent-polarizable layer (e.g., of the remanent-polarizable layer 406). Illustratively, ferroelectric materials may be used to store data in non-volatile manner in integrated circuits. The term “ferroelectric” may be used herein, for example, to describe a material that shows a hysteretic charge voltage relationship (Q-V). The ferroelectric material may be or may include at least one of the following: ferroelectric hafnium oxide (ferroelectric HfO₂), ferroelectric zirconium oxide (ferroelectric ZrO₂), a ferroelectric mixture of hafnium oxide and zirconium oxide. Ferroelectric hafnium oxide may include any form of hafnium oxide that may exhibit ferroelectric properties. Ferroelectric zirconium oxide may include any form of zirconium oxide that may exhibit ferroelectric properties. This may include, for example, hafnium oxide, zirconium oxide, a solid solution of hafnium oxide and zirconium oxide (e.g. but not limited to it a 1:1 mixture) or hafnium oxide and/or zirconium oxide doped or substituted with one or more of the following elements (non-exhaustive list): silicon, aluminum, gadolinium, yttrium, lanthanum, strontium, zirconium, any of the rare earth elements or any other dopant (also referred to as doping agent) that is suitable to provide or maintain ferroelectricity in hafnium oxide or zirconium oxide. The ferroelectric material may be doped at a concentration from about 2 mol % to about 6 mol %, only as an example.

A leakage current, I_{LEAK}, may be present in the capacitive memory structure 402. Illustratively, the amount of charge stored in the capacitive memory structure 402 may decrease over time, and a leakage current may originate from the capacitive memory structure 402. The capacitive memory structure 402 may be configured to reduce or prevent a leakage current I_{LEAK} of the capacitive memory structure 402 from charging electrically floating elements in a memory cell.

The capacitive memory structure 402 may include one or more (additional) electrically insulating layer 410 (also referred to herein as one or more bottom electrode charge-prevention layers 410), see for example FIG. 4B to FIG. 4E, configured to prevent leakage current-induced charging of electrically floating elements in a memory cell (e.g., charging of an electrically conductive connection coupling a field-effect transistor structure and the capacitive memory structure 402 with one another). In the following, reference is made to a bottom electrode charge-prevention layer 410, shown in FIG. 4B to FIG. 4E, it is however intended that the bottom electrode charge-prevention layer 410 may be understood as one or more bottom electrode charge-prevention layers 410.

The bottom electrode charge-prevention layer 410 may be disposed in various positions within the capacitive memory structure 402, e.g. disposed between the bottom electrode 404 and the top electrode 408 (for example, integrated into a usual remanent-polarizable layer 406 and/or disposed over and/or under a usual remanent-polarizable layer 406). Illustratively, the functional layer (e.g., the remanent-polarizable layer 406) of the capacitive memory structure 402 may be modified by including at least one additional electrically insulating layer that is referred to herein as bottom electrode charge-prevention layer 410, wherein, in the following, such a “modified” functional layer 416 (see FIG. 4B to FIG. 4E), e.g. such modified remanent-polarizable layer 416, is described in more detail.

In various aspects, the bottom electrode charge-prevention layer 410 may be an example of additional electrically insulating structure of a memory cell. A memory cell (e.g., the memory cell 100) may include a capacitive memory structure including a bottom electrode charge-prevention layer. Illustratively, the bottom electrode charge-prevention layer 410 may provide a containment of the leakage current I_{LEAK} such that charging of electrically floating elements induced by the leakage current I_{LEAK} originating from the capacitive memory structure may be substantially prevented.

The bottom electrode charge-prevention layer 410 may be configured in a similar manner as the gate electrode charge-prevention layer 312 described above in relation to FIG. 3A to FIG. 3F. The bottom electrode charge-prevention layer 410 may include an electrically insulating material, for example a dielectric material such as an oxide or a nitride material (e.g., Al₂O₃, AlN, AlOₓN_{y} or SiO₂ SiN, SIOₓN_{y}). In some aspects, the bottom electrode charge-prevention layer 410 may include one of the materials described above in relation to the first gate isolation layer 306a in FIG. 3A to FIG. 3F, e.g. a low-k dielectric material. In some aspects, the bottom electrode charge-prevention layer 410 may include e.g. one of the materials described above in relation to the second gate isolation layer 306b in FIG. 3A to FIG. 3F, e.g. a high-k dielectric material. In some aspects, the bottom electrode charge-prevention layer 410 may have a (total and/or individual) thickness in the range from about 0.5 nm to about 1.5 nm, for example from about 1 nm to about 3 nm.

The bottom electrode charge-prevention layer 410 may be understood as part of the functional layer 416. In some aspects, the bottom electrode charge-prevention layer 410 may include a different material with respect to the remanent-polarizable layer 406 (e.g., a material having a different dielectric constant and/or a different chemical composition, for example different doping, different content of the participating elements, or the like). In some aspects, the bottom electrode charge-prevention layer 410 may include a same material as the remanent-polarizable layer 406 (e.g., a material having a same dielectric constant and/or a same chemical composition).

In case, as an example, the bottom electrode charge-prevention layer 410 is formed of the same material as the remanent-polarizable layer 406, the layers may be formed by distinct deposition processes, wherein, as a result of the used distinct deposition processes, an interface region or interface layer may be present (e.g., including dislocations, defects, or other microstructural features) between the two adj acent layers indicating the presence of two distinct layers.

FIG. 4C and FIG. 4E show schematically a (modified) capacitive memory structure 402 including a modified functional layer 416, according to various aspects. Illustratively, the FIG. 4C and FIG. 4E show various exemplary dispositions of the bottom electrode charge-prevention layer 410 with respect to a (usual) remanent-polarizable layer 406. In some aspects the capacitive memory structure 402 may include a plurality of bottom electrode charge-prevention layers 410 (e.g., including the same electrically insulating material or different electrically insulating materials), for example disposed in different positions within the capacitive memory structure 402.

As illustrated in FIG. 4C, the bottom electrode charge-prevention layer 410 may be disposed between the at least one remanent-polarizable layer 406 and the second electrode 408, e.g. the bottom electrode charge-prevention layer 410 may be in direct physical contact with the at least one remanent-polarizable layer 406 and the second electrode 408. As illustrated in FIG. 4D, the bottom electrode charge-prevention layer 410 may be disposed between the at least one remanent-polarizable layer 406 and the first electrode 404, e.g. the bottom electrode charge-prevention layer 410 may be in direct physical contact with the at least one remanent-polarizable layer 406 and the first electrode 404.

It is however understood that other arrangements of the bottom electrode charge-prevention layer 410 are possible. As an example, the bottom electrode charge-prevention layer 410 may be disposed over the second electrode 408 or within the second electrode 408 (e.g., between a first portion and a second portion of the second electrode 408). As a further example, the bottom electrode charge-prevention layer 410 may be disposed below the first electrode 404 or within the first electrode 404 (e.g., between a first portion and a second portion of the first electrode 404). As another example, as shown for example in FIG. 4E, the bottom electrode charge-prevention layer 410 may be disposed within the at least one remanent-polarizable layer 406, e.g. as an interlayer sandwiched between a first portion 406a of the at least one remanent-polarizable layer 406 and a second portion 406b of the at least one remanent-polarizable layer 406.

FIG. 5A to FIG. 5G each illustrates schematically a possible integration scheme of a memory cell 500. The memory cell 500 may include a field-effect transistor structure 502 and a capacitive memory structure 520. The field-effect transistor structure 502 and the capacitive memory structure 520 may be coupled with one another, e.g. such that the field-effect transistor structure 502 and the capacitive memory structure 520 form a capacitive voltage divider C_{FET}/C_{CAP}, as described with reference to the memory cell 100 in FIG. 1. The memory cell 500 may be an exemplary realization of the memory cell 100 described in relation to FIG. 1. The memory cell 500 may be configured such that electrically floating elements (enclosed in FIG. 5A to FIG. 5G by the dotted line 540) may be protected against leakage current-induced charging, as described in further detail below. Illustratively, the floating elements 540 may include a gate electrode 508 of the field-effect transistor structure 502, a bottom electrode 522 of the capacitive memory structure 520, and a connection structure 534, as described in further detail below.

The field-effect transistor structure 502 may be configured as described above, e.g. with reference to the field-effect transistor structure 302 illustrated in FIG. 3A to FIG. 3F. The field-effect transistor structure 502 may include a gate structure 504 defining a channel region 510 in a semiconductor layer (e.g., as described for the gate structure 304 and the channel region 310 above). The gate structure 504 may include a gate electrode 508 and a gate isolation 506 disposed between the gate electrode 508 and the channel region 510 (e.g., as described for the gate isolation 306 and the gate electrode 308 above). In some aspects, the gate structure 504 may be embedded in (e.g., may be laterally surrounded by) a first insulator layer 532a (e.g., part of a metallization structure 530, described in further detail below). The first insulator layer 532a may include a dielectric material, e.g., silicon oxide (SiO2), silicon nitride (SiNₓ), etc (as described for the insulator layer 206 in relation to FIG. 2). In some aspects, the field-effect transistor structure 502 may optionally include a modified gate isolation (e.g., the modified gate isolation 316 described in relation to FIG. 3A to FIG. 3F above), e.g. the field-effect transistor structure 502 may optionally include a gate electrode charge-prevention layer (e.g., as described for the gate electrode charge-prevention layer 312 above, not shown in FIG. 5A to FIG. 5G) configured to prevent charging of (at least one of the) floating elements 540, e.g. in case it is determined that a leakage current originating from the field-effect transistor structure 502 may be of sufficient magnitude to be detrimental for the operations of the memory cell 500. The gate electrode charge-prevention layer may be disposed, as an example, between the gate electrode 508 and the channel region 510 (e.g., in any of the possible positions described in relation to FIG. 3C to FIG. 3F).

The capacitive memory structure 520 may be configured as described above, e.g. with reference to the capacitive memory structure 402 illustrated in FIG. 4A to FIG. 4E. The capacitive memory structure 520 may include a first electrode 522, a second electrode 526, and at least one remanent-polarizable layer 524 disposed between the first electrode 522 and the second electrode 526 (e.g., as described above for the first electrode 404, the second electrode 408, and the at least one remanent-polarizable layer 406 disposed therebetween). In some aspects, the capacitive memory structure 520 may be embedded in (e.g., may be laterally surrounded by) a third insulator layer 532c (e.g., part of a metallization structure 530, described in further detail below). The third insulator layer 532c may include a dielectric material, e.g., silicon oxide (SiO2), silicon nitride (SiNₓ), etc. (as described for the insulator layer 206 in relation to FIG. 2). In some aspects, the capacitive memory structure 520 may optionally include a modified functional layer (e.g., the modified functional layer 416 described in relation to FIG. 4A to FIG. 4E above), e.g. the capacitive memory structure 520 may optionally include a bottom electrode charge-prevention layer (e.g., as described for the bottom electrode charge-prevention layer 410 above, not shown in FIG. 5A to FIG. 5G) configured to prevent charging of (at least one of the) floating elements 540, e.g. in case it is determined that a leakage current originating from the capacitive memory structure 520 may be of sufficient magnitude to be detrimental for the operations of the memory cell 500. The bottom electrode charge-prevention layer may be disposed, as an example, between the first electrode 522 and the second electrode 526 (e.g., in any of the possible positions described in relation to FIG. 4B to FIG. 4E).

As described above with reference to the memory cell 100 in FIG. 1, the field-effect transistor structure 502 and the capacitive memory structure 520 may be connected with one another to form a capacitive voltage divider C_{FET}/C_{CAP}, e.g., by connecting one of the electrodes of the capacitive memory structure 520 (e.g., the first electrode 522) and the gate electrode 508 of the field-effect transistor structure 502 with one another. The electrically conductive connection of the capacitive memory structure 520 with the field-effect transistor structure 502 may provide a series capacitive connection between the capacitors formed by the capacitive memory structure 520 and the field-effect transistor structure 502.

In some aspects, the memory cell 500 may include a metallization structure 530 (also referred to herein as contact metallization) configured to electrically conductively connect the field-effect transistor structure 502 and the capacitive memory structure 520 with one another. The metallization structure 530 may be configured as the metallization structure 202 described in relation to FIG. 2.

The memory cell 500 (e.g., the metallization structure 530) may include a connection structure 534 coupling the capacitive memory structure 520 and the field-effect transistor structure 502 with one another. The connection structure 534 may electrically conductively connect the gate electrode 508 of the field-effect transistor structure 502 and the first electrode 522 of the capacitive memory structure 520 with one another. In some aspects, the connection structure 534 may be in direct physical contact with the gate electrode 508 of the field-effect transistor structure 502 and with the first electrode 522 of the capacitive memory structure 520. The connection structure 534 is described and illustrated as a single contact connecting the gate electrode 508 of the field-effect transistor structure 502 and the first electrode 522 of the capacitive memory structure 520 with one another. It is however understood, that the connection structure 534 may be or may include a plurality of contacts, for example disposed in multiple levels and connected with one another by one or more distribution layers. Illustratively, the metallization structure 530 may include a plurality of metallization structures, e.g. a plurality of single- or multi-level contact structures. In some aspects, the connection structure 534 may be a gate contact structure. In some aspects, the connection structure 534 may be configured as the contact structure 204 described above.

In some aspects, the connection structure 534 may be embedded in (e.g., may be laterally surrounded by) a second insulator layer 532b (e.g., configured as the insulator layer 206 described above). The second insulator layer 532b may include a dielectric material, e.g., silicon oxide (SiO2), silicon nitride, etc., having, for example, a thickness in the range from about 10 nm to about 100 nm, e.g., a thickness of about 40 nm. It is understood, that the connection structure 534 may be embedded in more than one insulator layer, e.g. in case the connection structure 534 is a multi-level contact between the field-effect transistor structure 502 and the capacitive memory structure 520. Illustratively, the connection structure 534 may be embedded in at least one insulator layer 532a, 532b, 532c. It is also understood, additionally or alternatively, that the connection structure 534 may be embedded in one or more metal levels. Illustratively, the connection structure 534 may extend across (in other words, through) one or more metal levels, for example from a contact level to a fourth metal level. In some aspects, the connection structure 534 may extend through at least one of the one or more insulator layers 532a, 532b, 532c and through at least one metal level.

The connection structure 534 may include an electrically conductive material, for example the connection structure 534 may include a metal (e.g., at least one metal layer), such as tungsten (W) or cobalt (Co), as examples, or any other conductive material (e.g., a metal alloy, a degenerate semiconductor, a polysilicon layer, etc.).

In some aspects, the connection structure 534 may be disposed over an active area of the field-effect transistor structure 502, and the capacitive memory structure 520 may be disposed over the connection structure 534 (i.e. over the active area of the field-effect transistor structure 402). This configuration may herein be referred to as capacitor over active area (COAA) structure. The COAA structure may allow providing a memory cell (e.g., the memory cell 500) with reduced overall (lateral) dimensions, e.g. for facilitating its application at the 28 nm technology node. By arranging the capacitive memory structure 520 (e.g., as ferroelectric capacitor) above the field-effect transistor structure 502 the full scaling potential may be maintained.

In some aspects, the memory cell 500 may have a footprint (defined by consumed area on a substrate (e.g., on a wafer) during integration thereof) that is less than 0.05 µm², for example less than 0.01 µm². In some aspects, a first footprint, F_{GE-FET}, may be associated with the gate electrode 508 of the field-effect transistor structure 502. The first footprint, F_{GE-FET}, may be less than 0.05 µm², for example less than 0.01 µm². In some aspects, a second footprint, F_{E-CAP}, may be associated with the first/second electrode of the capacitive memory structure 520. The second footprint, F_{E-CAP}, may be less than 0.05 µm², for example less than 0.01 µm². In some aspects, the first footprint may be less than 8 times (e.g., less than 4 times, e.g., substantially the same as) the second footprint (i.e., F_{GE-FET} < 8·F_{E-CAP}).

In the FIG. 5A to FIG. 5G the first insulator layer 532a, the second insulator layer 532b and the third insulator layer 532c are shown as separate layers. In some aspects, the first insulator layer 532a, the second insulator layer 532b and the third insulator layer 532c may also be understood as a same insulator layer. Illustratively, the metallization structure 530 may include one or more insulator layers (e.g., the first insulator layer 532a, the second insulator layer 532b and the third insulator layer 532c), into which contact structures (as well as the field-effect transistor structure 502 and the capacitive memory structure 520) may be embedded. The one or more insulator layers 532a, 532b, 532c may also be referred to herein as one or more electrically insulating layers 532a, 532b, 532c of the metallization structure 530. In the present description, the terms “electrically isolating” and “electrically insulating” may be used interchangeably. Similarly, the terms “(electrical) isolation” and “(electrical) insulation” may be used interchangeably.

The electrically conductive connection between the field-effect transistor structure 502 and the capacitive memory structure 520 may be electrically floating (e.g., as described above for the floating node 124 in relation to FIG. 1). Illustratively, the connection structure 434 may be electrically floating. In some aspects, the gate electrode 508 of the field-effect transistor structure 502, the connection structure 534, and the first electrode 522 of the capacitive memory structure 520 may be electrically floating.

In some aspects, the memory cell 500 (e.g., the metallization structure 530) may include one or more source/drain contact structures 536s, 536d, to electrically contact the field-effect transistor structure 502. The one or more source/drain contact structures 536s, 536d may be configured to allow a control of the memory cell 500. In some aspects, the one or more source/drain contact structures 536s, 536d may be referred to as one or more source/drain contact structures 536s, 536d. In some aspects, the one or more source/drain contact structures 536s, 536d may be configured to allow access to the field-effect transistor structure 502, e.g. may allow providing one or more (source/drain) voltages at the field-effect transistor structure 502. As an example, the one or more source/drain contact structures 536s, 536d may allow providing one or more readout voltages to read out a state the memory cell 500 is residing in. As another example, the one or more source/drain contact structures 536s, 536d may allow providing one or more write voltages at the memory cell 500, e.g. at the field-effect transistor structure 502, e.g. to switch a memory state the memory cell 500 is residing in.

The one or more source/drain contact structures 536s, 536d may be embedded in (e.g., laterally surrounded by) at least one of the one or more insulator layers 532a, 532b, 532c of the metallization structure 530 (e.g., in the exemplary configuration in FIG. 5A to FIG. 5G the one or more source/drain contact structures 536s, 536d may be embedded in the one or more insulator layers, e.g. in the first insulator layer 532a, the second insulator layer 532b, and the third insulator layer 532c). The one or more source/drain contact structures 536s, 536d may (each) include an electrically conductive material, for example the one or more source/drain contact structures 536s, 536d may include a metal (e.g., at least one metal layer), such as tungsten (W) or cobalt (Co), as examples, or any other conductive material (e.g., a metal alloy, a degenerate semiconductor, a polysilicon layer, etc.). In some aspects, the one or more source/drain contact structures 536s, 536d may be configured as the contact structure 204 described in relation to FIG. 2. The one or more source/drain contact structures 536s, 536d may also be referred to herein as one or more source/drain contact plugs, or one or more source/drain plugs. It is also understood, additionally or alternatively, that one or more source/drain contact structures 536s, 536d may be embedded in one or more metal levels.

In some aspects, the one or more control source/drain structures 536s, 536d may contact respective source/drain regions of the field-effect transistor structure 502 (not shown in FIG. 5A to FIG. 5G). In some aspects, the one or more source/drain contact structures 536s, 536d may include a first source/drain contact structure contacting a first source/drain region of the field-effect transistor structure 502 and a second source/drain contact structure 536s, 536d contacting a second source/drain region of the field-effect transistor structure. The one or more source/drain contact structures 536s, 536d may allow providing one or more source/drain voltages at the field-effect transistor structure 502 (e.g., at the respective source/drain region), e.g. for controlling a readout operation and/or a write operation of the memory cell 500.

A leakage current may originate from the one or more source/drain contact structures 536s, 536d, e.g. in direction of the floating elements 540. Providing a (high) voltage (e.g., greater than 3 V) via the one or more source/drain contact structures 536s, 536d may have the risk that the floating elements 540 may be charged by leakage currents, e.g. currents tunneling through the one or more insulator layers 532a, 532b, 532c. Illustratively, the one or more insulator layers 532a, 532b, 532c of the metallization structure 530 may not be (always) sufficient to protect the floating elements 540 from undesired charging.

By way of example, a leakage current originating from the one or more source/drain contact structures 536s, 536d may be problematic in case the one or more control source/drain structures 536s, 536d are in close proximity to the floating elements 540 (e.g., to at least one of the first electrode 524, the gate electrode 508, or the connection structure 534), e.g. in case the lateral dimensions of the memory cell 500 are reduced. In some aspects, a shortest distance between at least one of the first electrode 524, the gate electrode 508, or the connection structure 534 and at least one of the one or more source/drain contact structures 536s, 536d may be below a threshold distance. The threshold distance may be a distance below which it may be more likely that a leakage current may flow (e.g., tunnel) from a source/drain contact structures 536s, 536d to floating element in close proximity. In some aspects, the threshold distance may be in the range from about 1 nm to about 1 µm, for example the threshold distance may be 50 nm or 20 nm.

In various aspects, the memory cell 500 may include one or more additional electrically insulating structures configured to prevent a leakage current-induced charging of the floating elements 540, e.g. to prevent a leakage current-induced charging of (at least one of) the first electrode 522, the gate electrode 508, and the connection structure 534, described in further detail below in relation to FIG. 5B to FIG. 5G. The one or more additional electrically insulating structures may be disposed between a respective floating element and the one or more source/drain contact structures 536s, 536d. In some aspects, the one or more additional electrically insulating structures may include one or more electrically insulating layers at least partially surrounding at least one of a sidewall of the connection structure 534, a sidewall of the first electrode 522, or a sidewall of the gate electrode 508, as described in relation to FIG. 5B to FIG. 5G below. The (at least one) sidewall that is covered by the one or more electrically insulating layers may face at least one of the one or more source/drain contact structures 536s, 536d (e.g., a source/drain contact structure in close proximity to the covered sidewall).

The one or more additional electrically insulating structures may be distinct from the one or more insulator layers 532a, 532b, 532c of the metallization structure 530, e.g. the one or more additional electrically insulating structures may be provided in addition to the one or more insulator layers 532a, 532b, 532c and may have different properties, as described in further detail below. In the FIG. 5B to FIG. 5G various examples of possible additional electrically insulating structures are provided, shown separately from one another. It is however understood that a memory cell (e.g., the memory cell 500) may include one, or more than one, or all the additional electrically insulating structures described herein (see for example FIG. 5G), e.g. in any possible combination.

The one or more additional electrically insulating structures may include (in some aspects may consist of) at least one (first) material that is different from a (second) material of the one or more insulator layers 532a, 532b, 532c of the metallization structure 530. In some aspects, the first material of the one or more additional electrically insulating structures may include a different chemical composition and/or a different microstructure with respect to a material of the one or more insulator layers 532a, 532b, 532c of the metallization structure 530. In some aspects, the first material of the one or more additional electrically insulating structures may differ from the second material of the one or more insulator layers 532a, 532b, 532c in at least one of the following properties: crystal structure (e.g., phase of the material), microstructure (e.g., grain size, grain shape, distribution of grain boundaries, and the like), a chemical element, and/or a chemical composition (e.g., different doping, different content of the participating elements, or the like). In some aspects, the first material of the one or more additional electrically insulating structures may have a higher crystal quality compared to the second material of the one or more insulator layers 532a, 532b, 532c. The relatively higher crystal quality may ensure improved electrical insulation properties with respect to the one or more insulator layers 532a, 532b, 532c. In a conventional memory cell it may be inconvenient, in terms of fabrication, to provide large and/or thick electrically insulating layers with high crystal quality. The one or more additional electrically insulating structures may be comparatively thin with respect to the one or more insulator layers 532a, 532b, 532c, e.g. the one or more additional electrically insulating structures may have a thickness less than 20 nm, for example less than 10 nm or less than 5 nm, so that it may be possible to devote the fabrication efforts to provide the quality needed for better protecting the floating elements 540. The material of the one or more additional electrically insulating structures described herein may be a material of one or more electrically insulating layers 542 of the connection structure 534 and/or of one or more electrically insulating layers 544 of the one or more source/drain contact structures 536s, 436d, and/or of one or more electrically insulating layers 546 surrounding the capacitive memory structure 520, and/or of one or more electrically insulating layers 548 surrounding the field-effect transistor structure 502, described in further detail below. In some aspects, the material of the one or more additional electrically insulating structures described herein may be a material of a gate electrode charge-prevention layer and/or of a bottom electrode charge-prevention layer, described above.

In some aspects, as shown in FIG. 5B, the one or more additional electrically insulating structures may include one or more electrically insulating layers 542 (also referred to herein as one or more connection charge-prevention layers 542) at least partially surrounding (e.g., covering) a sidewall of the connection structure 534. The one or more connection charge-prevention layers 542 may be configured as the one or more contact charge-prevention layers 208 described in relation to FIG. 2. In the following, reference is made to a connection charge-prevention layer 542, it is however intended that the connection charge-prevention layer 542 may be understood as one or more connection charge-prevention layers 542.

In some aspects, the connection charge-prevention layer 542 may include an electrically insulating material, for example a dielectric material such as an oxide or a nitride material (e.g., Al₂O₃, AlN, AlOₓN_{y} or SiO₂ SiN, SIOₓN_{y}). In some aspects, connection charge-prevention layer 542 may include one of the materials described in relation to the first gate isolation layer 306a in FIG. 3A to FIG. 3F, e.g. a low-k dielectric material. In some aspects, the connection charge-prevention layer 542 may include one of the materials described in relation to the second gate isolation layer 306b in FIG. 3A to FIG. 3F, e.g. a high-k dielectric material.

The sidewall of the connection structure 534 that is covered by the connection charge-prevention layer 542 may be facing at least one of the one or more source/drain contact structures 536s, 536d. In some aspects the sidewall of the connection structure 534 that is covered by the connection charge-prevention layer 542 may be facing a (e.g., the at least one) source/drain contact structure 536s, 536d arranged at a distance less than the threshold distance from the connection structure 534. In some aspects, the connection charge-prevention layer 542 may completely laterally surround the sidewall of the connection structure 534. In some aspects, the connection charge-prevention layer 542 may be conformally deposited on the sidewall of the connection structure 534, e.g. by means of a conformal deposition process such as atomic layer deposition or molecular layer deposition. The conformal deposition of the connection charge-prevention layer 542 may allow providing a layer with relatively high(er) crystal quality. Illustratively, the connection charge-prevention layer 542 may be (conformally) deposited onto at least a portion of a sidewall of an opening (e.g., a trench) formed in at least one of the one or more insulator layers 532a, 532b, 532c (e.g., in the second insulator layer 532b) prior to the deposition of the conductive material of the connection structure 534. In some aspects, the connection charge-prevention layer 542 may be disposed between the connection structure 534 and at least one of the one or more insulator layers 532a, 532b, 532c, e.g. the connection charge-prevention layer 542 may be in direct physical contact with at least one of the one or more insulator layers 532a, 532b, 532c (e.g., with the second insulator layer 532b).

In some aspects, the sidewall of the connection structure 534 that is covered by the connection charge-prevention layer 542 is at a same level as (at least a portion of) the one or more source/drain contact structures 536s, 536d, e.g. at the same level as at least a portion of at least one of the one or more source/drain contact structures 536s, 536d (e.g., the source/drain contact structure arranged in close proximity to the connection structure 534). Being at the same level may be understood as the covered sidewall of the connection structure 534 being at a same (vertical) distance from the substrate (e.g., from the semiconductor layer) as the at least a portion of the at least one of the one or more source/drain contact structures 536s, 536d. Illustratively, a projection of the connection charge-prevention layer 542 in the horizontal direction (e.g., in the direction pointed by the arrows in FIG. 5B) may hit a portion of at least one of the one or more source/drain contact structures 536s, 536d.

In some aspects, as shown in FIG. 5C, the one or more additional electrically insulating structures may include one or more additional electrically insulating layers 544 (also referred to herein as one or more source/drain charge-prevention layers 544) at least partially surrounding (e.g., covering) a sidewall of at least one source/drain contact structure 536s, 536d of the one or more source/drain contact structures 536s, 536d. In some aspects, the one or more source/drain charge-prevention layers 544 may include a plurality of source/drain charge-prevention layers 544 each at least partially surrounding a sidewall of a respective source/drain contact structure 536s, 536d. In the following, reference may be made to a source/drain charge-prevention layer 544, it is however intended that the source/drain charge-prevention layer 544 may be understood as one or more source/drain charge-prevention layers 544.

The control source/drain charge-prevention layer 544 may be configured as the contact charge-prevention layer 208 described in relation to FIG. 2. In some aspects, the source/drain charge-prevention layer 544 may include an electrically insulating material, for example a dielectric material such as an oxide or a nitride material (e.g., Al₂O₃, AlN, AlOₓN_{y} or SiO₂ SiN, SIOₓN_{y}). In some aspects, the source/drain charge-prevention layer 544 may include one of the materials described above in relation to the first gate isolation layer 306a in FIG. 3A to FIG. 3F, e.g. a low-k dielectric material. In some aspects, the source/drain charge-prevention layer 544 may include one of the materials described above in relation to the second gate isolation layer 306b in FIG. 3A to FIG. 3F, e.g. a high-k dielectric material.

The sidewall of the (respective) source/drain contact structure 536s, 536d that is covered by the source/drain charge-prevention layer 544 may be facing at least one of the floating elements 540, e.g. at least one of the connection structure 534, the gate electrode 508, or the bottom electrode 522. In some aspects, the sidewall of a source/drain contact structure 536s, 536d that is covered by the source/drain charge-prevention layer 544 may be at a same level as at least one of the floating elements 540, e.g. at a same level as at least one of the connection structure 534, the gate electrode 508, or the bottom electrode 522. Illustratively, the sidewall of a source/drain contact structure 536s, 536d that is covered by the (respective) source/drain charge-prevention layer 544 may horizontally project (e.g., as indicated by the arrows in FIG. 5C) onto at least one of the floating elements 540. In some aspects, thesource/drain charge-prevention layer 544 may completely laterally surround the sidewall of the (respective) source/drain contact structure 536s, 536d.

In some aspects, the source/drain charge-prevention layer 544 may at least partially surround the sidewall of the (respective) source/drain contact structure 536s, 536d in case a distance between the source/drain contact structure 536s, 536d and at least one of the floating elements 540 is less than the threshold distance. In some aspects, a sidewall of each source/drain contact structure 536s, 536d disposed at a distance from at least one of the floating elements 540 that is less than the threshold distance may be at least partially surrounded by a source/drain charge-prevention layer 544.

In some aspects, the source/drain charge-prevention layer 544 may be conformally deposited on the sidewall of the (respective) source/drain contact structure 536s, 536d, e.g. by means of a conformal deposition process such as atomic layer deposition or molecular layer deposition. The conformal deposition of the source/drain charge-prevention layer 544 may allow providing a layer with relatively high(er) crystal quality. Illustratively, the source/drain charge-prevention layer 544 may be (conformally) deposited onto a sidewall of an opening formed in at least one of the one or more insulator layers 532a, 532b, 532c (e.g., in the first insulator layer 532a, in the second insulator layer 532b, and in the third insulator layer 532c) prior to the deposition of the conductive material of the source/drain contact structure 536s, 536d. In some aspects, the source/drain charge-prevention layer 544 may be disposed between the source/drain contact structure 536s, 536d and at least one of the one or more insulator layers 532a, 532b, 532c, e.g. the source/drain charge-prevention layer 544 may be in direct physical contact with at least one of the one or more insulator layers 532a, 532b, 532c (e.g., with the second insulator layer 532b).

In some aspects, as shown in FIG. 5D, the one or more additional electrically insulating structures may include one or more electrically insulating layers 546 (also referred to as one or more memory charge-prevention layers 546) at least partially surrounding the capacitive memory structure 520. In the following, reference may be made to a memory charge-prevention layer 546, it is however intended that the memory charge-prevention layer 546 may be understood as one or more memory charge-prevention layers 546.

The memory charge-prevention layer 546 may be disposed between the capacitive memory structure 520 and at least one of the one or more source/drain contact structures 536s, 536d (in some aspects, between the capacitive memory structure 520 and each of the one or more control source/drain contact structures 536s, 536d). The memory charge-prevention layer 546 may horizontally project onto at least one of the one or more source/drain contact structures 536s, 536d. In various aspects the memory charge-prevention layer 546 may have a width in the range from about 0.5 nm to about 5 nm, e.g., a width of 3 nm.

In some aspects, the memory charge-prevention layer 546 may include an electrically insulating material, for example a dielectric material such as an oxide or a nitride material (e.g., Al₂O₃, AlN, AlOₓN_{y} or SiO₂ SiN, SIOₓN_{y}). In some aspects, the memory charge-prevention layer 546 may include one of the materials described above in relation to the first gate isolation layer 306a in FIG. 3A to FIG. 3F, e.g. a low-k dielectric material. It is however understood that any other material may be used that allows a conformal deposition for providing the memory charge-prevention layer 546.

In some aspects, the memory charge-prevention layer 546 may surround the capacitive memory structure 520, e.g. the memory charge-prevention layer 546 may at least partially surround at least the portion of the capacitive memory structure 520 part of the floating elements 540 (e.g., at least the first electrode 522 of the capacitive memory structure 520). Illustratively, the first electrode 522 may be disposed between a first portion of the memory charge-prevention layer 546 and a second portion of the memory charge-prevention layer 546. The memory charge-prevention layer 546 may be disposed between the first electrode 522 of the capacitive memory structure 520 and at least one of the one or more insulator layers 532a, 532b, 532c (e.g., the third insulator layer 532c). In some aspects, the memory charge-prevention layer 546 may surround the first electrode 522, the at least one remanent-polarizable layer 524, and the second electrode 526 of the capacitive memory structure 520.

In some aspects, as shown in FIG. 5E and FIG. 5F, the one or more additional electrically insulating structures may include one or more electrically insulating layers 548 (also referred to as one or more transistor charge-prevention layers 548) at least partially surrounding the field-effect transistor structure 502. In the following, reference may be made to a transistor charge-prevention layer 548, it is however intended that the transistor charge-prevention layer 548 may be understood as one or more transistor charge-prevention layers 548.

The transistor charge-prevention layer 548 may be disposed between the field-effect transistor structure 502 and at least one of the one or more source/drain contact structures 536s, 536d (in some aspects, between the field-effect transistor structure 502 and each of the one or more control source/drain contact structures 536s, 536d). The transistor charge-prevention layer 548 may horizontally project onto at least one of the one or more source/drain contact structures 536s, 536d. In various aspects the transistor charge-prevention layer 548 may have a width in the range from about 0.5 nm to about 5 nm, e.g., a width of 3 nm.

In some aspects, the transistor charge-prevention layer 548 may include an electrically insulating material, for example a dielectric material such as an oxide or a nitride material (e.g., Al₂O₃, AlN, AlOₓN_{y} or SiO₂ SiN, SIOₓN_{y}). In some aspects, the transistor charge-prevention layer 548 may include one of the materials described above in relation to the first gate isolation layer 306a in FIG. 3A to FIG. 3F, e.g. a low-k dielectric material. It is however understood that any other material may be used that allows a conformal deposition for providing the transistor charge-prevention layer 548.

In some aspects, the transistor charge-prevention layer 548 may surround the field-effect transistor structure 502, e.g. the transistor charge-prevention layer 548 may surround at least the portion of the field-effect transistor structure 502 part of the floating elements 540 (e.g., at least the gate electrode 508 of the field-effect transistor structure 502). In some aspects, the transistor charge-prevention layer 548 may at least partially surround the gate electrode 508 of the field-effect transistor structure 502. Illustratively, the gate electrode 508 may be disposed between a first portion of the transistor charge-prevention layer 548 and a second portion of the transistor charge-prevention layer 548. In some aspects, the transistor charge-prevention layer 548 may (additionally) surround the gate isolation 506 of the field-effect transistor structure 502. In some aspects, the transistor charge-prevention layer 548 may at least partially cover a surface of the field-effect transistor structure 502 facing the capacitive memory structure 520 (see FIG. 5F), e.g. a surface of the gate electrode 508 facing the capacitive memory structure 520.

As shown in FIG. 5G, a memory cell 500 may include a plurality of additional electrically insulating structures, e.g. a connection charge-prevention layer 542, one or more source/drain charge-prevention layers 544, a memory charge-prevention layer 546, and a transistor charge-prevention layer 548.

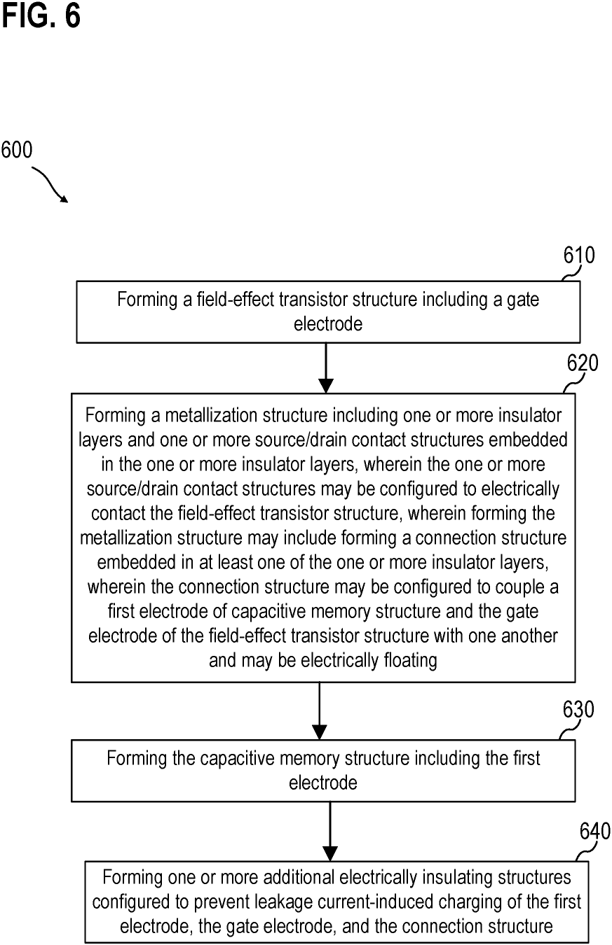

FIG. 6 illustrates a schematic flow diagram of a method 600 for processing a memory cell, e.g. for processing the memory cell 100 described in relation to FIG. 1 and/or the memory cell 500 described in relation to FIG. 5A to FIG. 5G, according to various aspects.

The method 600 may include: in 610 forming a field-effect transistor structure including a gate electrode (e.g., the field-effect transistor structure 102, the field-effect transistor structure 302, the field-effect transistor structure 502, described above). The field-effect transistor structure may include, in some aspects, a channel region, and a gate isolation disposed between the gate electrode and the channel region.

The method 600 may include: in 620 forming a metallization structure (e.g., the metallization structure 202, the metallization structure 530, described above). The metallization structure may include one or more insulator layers (e.g., a first insulator layer, a second insulator layer, and a third insulator layer). The metallization structure may include one or more source/drain contact structures embedded in the one or more insulator layers, wherein the one or more source/drain contact structures may be configured to electrically contact the field-effect transistor structure.

Forming the metallization structure may include forming a connection structure embedded in at least one of the one or more insulator layers, wherein the connection structure may be configured to couple a first (e.g., bottom) electrode of capacitive memory structure and the gate electrode of the field-effect transistor structure with one another and may be electrically floating.

In some aspects, forming the metallization structure may be carried out after forming the field-effect transistor structure.

The method 600 may include: in 630 forming the capacitive memory structure including the first electrode (e.g., the capacitive memory structure 104, the capacitive memory structure 402, the capacitive memory structure 520, described above). The capacitive memory structure may include, in some aspects, a second electrode, and at least one remanent-polarizable layer arranged between the first electrode and the second electrode. In some aspects, forming the capacitive memory structure may be carried out after forming the metallization structure, e.g. after forming the connection structure.

The method may include: in 640, forming one or more additional electrically insulating structures (e.g., as described above in relation to FIG. 2A to FIG. 5G) configured to prevent leakage current-induced charging of the first electrode, the gate electrode, and the connection structure (in some aspects, of at least one of the first electrode, the gate electrode, and the connection structure).

In various aspects, forming the one or more additional electrically insulating structures may include conformally depositing an electrically insulating layer (or a plurality of electrically insulating layers). Forming the one or more additional electrically insulating structures may include conformally depositing an electrically insulating layer to at least partially surround the sidewall of the connection structure and/or conformally depositing an electrically insulating layer to at least partially surround the sidewall of at least one of the one or more source/drain contact structures. Illustratively, forming the one or more additional electrically insulating structures may include forming an opening (e.g., a trench) in at least one of the one or more insulator layers and conformally depositing an electrically insulating layer to at least partially surround the sidewall of the opening. The trench having the covered sidewall may subsequently be filled with at least one conductive material, e.g. a metal, such as tungsten (W) or cobalt (Co), as examples, or any other conductive material (e.g., a metal alloy, a degenerate semiconductor, a polysilicon layer, etc.).

In some aspects, forming the one or more additional electrically insulating structures may include conformally depositing an electrically insulating layer to at least partially surround the capacitive memory structure and/or conformally depositing an electrically insulating layer to at least partially surround the field-effect transistor structure.

In some aspects, forming the one or more additional electrically insulating structures may include forming a gate electrode charge-prevention layer in the field-effect transistor structure. In some aspects, forming the one or more additional electrically insulating structures may include forming a bottom electrode charge-prevention layer in the capacitive memory structure.

In some aspects, the method 600 may include one or more layering and patterning processes for processing the memory cell, e.g. for forming the memory structure and/or the field-effect transistor structure and/or the one or more additional electrically insulating structures.

The layering may include forming a gate isolation and a gate electrode. The patterning may include forming a mask (e.g., a silicon nitride hard mask having a thickness in the range from about 5 nm to about 100 nm) defining the lateral dimension of the field-effect transistor structure, e.g. of a gate structure thereof, and partially removing the gate isolation and the gate electrode.

Forming the field-effect transistor structure may include forming doped regions in a carrier, e.g. in a semiconductor layer, e.g. to form at least two source/drain regions of the field-effect transistor structure. Various doping techniques may be used to form the at least two source/drain regions, e.g. diffusion doping, ion implantation, or the like. Forming the field-effect transistor structure may include layering and patterning a gate structure at a (channel) region between the doped regions forming the at least two source/drain regions.

The layering may include forming a first electrode layer (e.g., a bottom electrode layer), a second electrode layer (e.g., a top electrode layer), and at least one remanent-polarizable layer disposed between the two electrode layers. The patterning may include forming a mask (e.g., a silicon nitride hard mask having a thickness in the range from about 5 nm to about 100 nm) defining the lateral dimension of the capacitive memory structure and partially removing the electrode layers and the at least one remanent-polarizable layer to form the capacitive memory structure. The capacitive memory structure may be formed over a metallization structure (illustratively the contact metallization) including a connection structure.

The layering may include forming one or more insulator layers (e.g., a first insulator layer, a second insulator layer, and a third insulator layer). The patterning may include forming a mask defining one or more openings to be formed in the one or more insulator layers.

In various aspects, one or more patterning processes may be used to form a field-effect transistor structure and/or a capacitive memory structure and/or one or more additional electrically insulating structures, e.g., at least one of over or in a carrier. Therefore, a mask may be used. A mask may include a material that serves for transferring a photo-lithography mask pattern into one or more material layers. A mask may include, for example, a positive or negative photo resist (also referred to as soft mask) or a hard mask. The photo resist itself may be patterned by standard lithography processes. The patterning of the hard mask material may include a combination of photo resist patterning followed by etch of the hard mask material (e.g. wet or dry chemical etching). However, any other suitable process may be used to transfer a desired pattern into one or more material layers.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

In like manner, the word “cover”, used herein to describe a feature disposed over another, e.g. a layer “covering” a side or surface, may be used to mean that the feature, e.g. the layer, may be disposed over, and in direct contact with, the implied side or surface. The word “cover”, used herein to describe a feature disposed over another, e.g. a layer “covering” a side or surface, may be used to mean that the feature, e.g. the layer, may be disposed over, and in indirect contact with, the implied side or surface with one or more additional layers being arranged between the implied side or surface and the covering layer.

The term “lateral” used with regards to a lateral dimension (in other words a lateral extent) of a structure, a portion, a structure element, a layer, etc., provided, for example, over and/or in a carrier (e.g. a layer, a substrate, a wafer, etc.) or “laterally” next to, may be used herein to mean an extent or a positional relationship along a surface of the carrier. That means that a surface of a carrier (e.g. a surface of a layer, a surface of a substrate, a surface of a wafer, etc.) may serve as reference, commonly referred to as the main processing surface. Further, the term “width” used with regards to a “width” of a structure, a portion, a structure element, a layer, etc., may be used herein to mean the lateral dimension (or in other words the lateral extent) of a structure. Further, the term “height” used with regards to a height of a structure, a portion, a structure element, a layer, etc., may be used herein to mean a dimension (in other words an extent) of a structure in a direction perpendicular to the surface of a carrier (e.g. perpendicular to the main processing surface of a carrier). The term “thickness” used with regards to a “thickness” of a layer may be used herein to mean the dimension (in other words an extent) of the layer perpendicular to the surface of the support (the material or material structure) on which the layer is deposited. If a surface of the support is parallel to the surface of the carrier (e.g. parallel to the main processing surface) the “thickness” of the layer deposited on the surface of the support may be the same as the height of the layer.

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g. provided by a metal or degenerate semiconductor in absence of p-n junctions in the current path. The term “electrically conductively connected” may be also referred to as “galvanically connected”.

The term region used with regards to a “source region”, “drain region”, “channel region”, and the like, may be used herein to mean a continuous region of a semiconductor layer (e.g., of a semiconductor wafer or a part of a semiconductor wafer, a semiconductor portion, a fin, a semiconductor nanosheet, a semiconductor nanowire, etc.,). In some aspects, the continuous region of a semiconductor layer may be provided by semiconductor material having only one dominant doping type.

The term “conform” or “conformally” used with regards to a layer (e.g. a spacer layer, a liner layer, etc.) may be used herein to mean that the layer may have substantially the same thickness along an interface with another structure, e.g. the shape of a surface of a conformal layer may be substantially the same as the shape as of a surface of the underlying structure on which the layer is formed. According to various embodiments, layering processes such as plating or several chemical vapor processes (CVD), e.g. low pressure (LP)-(CVD), atomic layer deposition (ALD), molecular layer deposition (MLD), etc., may be used to generate a conformal layer of a material. A conformal deposition process may allow covering sidewalls completely, e.g., even if the sidewall is aligned vertical to the surface of the carrier and/or parallel to the deposition direction. A sidewall may be, for example, generated by an opening (as for example a trench, a recess, a through hole, etc.) or by a structure element (as for example a fin, a protrusion, etc.).

The term “layer” may be used herein to mean a continuous or non-continuous region of a same material. A layer may be for example a region including the material forming the layer. As an example, a “semiconductor layer” may describe a continuous or non-continuous region of semiconductor material. A “semiconductor layer” may be understood, for example, as a semiconductor wafer, as a semiconductor portion (e.g., of a semiconductor wafer), as a layer of semiconductor material disposed in or over a carrier. As another example, an “electrically insulating layer” may describe a continuous or non-continuous region of electrically insulating material. An “electrically insulating layer” may be understood, for example, as a layer at least partially covering a surface (e.g., a sidewall, a top surface, a bottom surface) of an element, or as a region of electrically insulating layer.

In the following, various aspects of this disclosure will be illustrated.

Example 1 is a memory cell including: a capacitive memory structure including a first electrode; a field-effect transistor structure including a gate electrode; one or more insulator layers; one or more source/drain contact structures embedded in the one or more insulator layers to electrically contact the field-effect transistor structure; and a connection structure embedded in at least one of the one or more insulator layers, wherein the connection structure electrically conductively connects the first electrode of the capacitive memory structure and the gate electrode of the field-effect transistor structure with one another and is electrically floating, and one or more additional electrically insulating structures configured to prevent a leakage current-induced charging of the first electrode, the gate electrode, and the connection structure (in some aspects, of at least one of the first electrode, the gate electrode, and the connection structure).

In example 2, the memory cell according to example 1 may optionally further include that a shortest distance from at least one of the first electrode, the gate electrode, or the connection structure to at least one of the one or more source/drain contact structures is in the range from about 1 nm to about 1 µm.

In example 3, the memory cell according to example 1 or 2 may optionally further include that the one or more additional electrically insulating structures include one or more electrically insulating layers at least partially surrounding at least one of a sidewall of the connection structure, a sidewall of the first electrode, or a sidewall of the gate electrode.

In example 4, the memory cell according to example 3 may optionally further include that the sidewall that is covered by the one or more electrically insulating layers faces at least one of the one or more source/drain contact structures.

As an example the sidewall that is covered by the one or more electrically insulating layers faces a source/drain contact structure disposed at a distance in the range from about 1 nm to about 1 µm from at least one of the first electrode, the gate electrode, or the connection structure.

In example 5, the memory cell according to example 3 or 4 may optionally further include that the one or more additional electrically insulating structures include one or more electrically insulating layers at least partially surrounding the first electrode of the capacitive memory structure. The one or more electrically insulating layers may be disposed between the first electrode of the capacitive memory structure and at least one of the one or more insulator layers.

As an example, the one or more electrically insulating layers may at least partially surround the first electrode, the second electrode, and the at least one remanent-polarizable layer of the capacitive memory structure.

In example 6, the memory cell according to any one of examples 1 to 5 may optionally further include that the one or more additional electrically insulating structures include one or more electrically insulating layers at least partially covering a surface of the gate electrode of the field-effect transistor structure, the surface facing the capacitive memory structure.

In example 7, the memory cell according to any one of examples 1 to 6 may optionally further include that the one or more additional electrically insulating structures include one or more electrically insulating layers at least partially surrounding a sidewall of at least one source/drain contact structure of the one or more source/drain contact structures. The one or more electrically insulating layers may be disposed between the at least one source/drain contact structure and the one or more insulator layers.

In example 8, the memory cell according to example 7 may optionally further include that the sidewall of the at least one source/drain contact structure faces at least one of the connection structure, the first electrode, or the gate electrode.

In example 9, the memory cell according to any one of examples 1 to 8 may optionally further include that the field-effect transistor structure includes a semiconductor layer and at least a first source/drain region and a second source/drain region disposed in the semiconductor layer. The one or more source/drain contact structures may include a first source/drain contact structure and a second source/drain contact structure contacting the first source/drain region and the second source/drain region respectively.

In example 10, the memory cell according to any one of examples 1 to 9 may optionally further include that the one or more additional electrically insulating structures include at least one first material that is different from a second material of the one or more insulator layers.

In example 11, the memory cell according to example 10 may optionally further include that the first material of the one or more additional electrically insulating structures differs from the second material of the one or more insulator layers in at least one of the following properties: a crystal structure, a microstructure, a chemical element, and/or a chemical composition.

As an example, the first material of the one or more additional electrically insulating structures may include a higher crystal quality with respect to the second material of the one or more insulator layers of the metallization structure.

In example 12, the memory cell according to any one of examples 1 to 11 may optionally further include that the capacitive memory structure further includes one or more electrically insulating layers disposed between the first electrode and a second electrode of the capacitive memory structure, the one or more electrically insulating layers being configured to prevent leakage current induced charging of the first electrode, the gate electrode, and the connection structure.

In example 13, the memory cell according to any one of examples 1 to 12 may optionally further include that the field-effect transistor structure further includes one or more electrically insulating layers disposed between a channel region and the gate electrode of the field-effect transistor structure, the one or more electrically insulating layers being configured to prevent leakage current-induced charging of the first electrode, the gate electrode, and the connection structure.

In example 14, the memory cell according to any one of examples 1 to 13 may optionally further include that the capacitive memory structure further includes a second electrode and at least one remanent-polarizable layer arranged between the first electrode and the second electrode.

In example 15, the memory cell according to example 14 may optionally further include that the at least one remanent-polarizable layer includes at least one ferroelectric material.

In example 16, the memory cell according to example 15 may optionally further include that the at least one ferroelectric material includes at least one of the following materials: ferroelectric hafnium oxide, ferroelectric zirconium oxide, a ferroelectric mixture of hafnium oxide and zirconium oxide.

In example 17, the memory cell according to any one of examples 1 to 16 may optionally further include that the capacitive memory structure and the field-effect transistor structure are coupled with one another to form a capacitive voltage divider.

In example 20, the memory cell according to any one of examples 1 to 19 may optionally further include that the memory cell is a non-volatile memory cell.

Example 21 is a memory cell including: a capacitive memory structure including a first electrode, a second electrode, and at least one remanent-polarizable layer disposed between the first electrode and the second electrode; a field-effect transistor structure including a channel region, a gate electrode, and a first gate isolation layer (e.g., a buffer layer) and a second gate isolation layer, the first gate isolation layer including a first material having a first dielectric constant and a first chemical composition, and the second gate isolation layer including a second material having a second dielectric constant and a second chemical composition, wherein the first dielectric constant is different from the second dielectric constant and/or the first chemical composition is different from the second chemical composition, wherein the first gate isolation layer and the second gate isolation layer are disposed between the gate electrode and the channel region; and an electrically conductive connection coupling the capacitive memory structure and the field-effect transistor structure with one another to form a capacitive voltage divider, wherein the electrically conductive connection is electrically floating, wherein the capacitive memory structure further includes one or more electrically insulating layers configured to prevent leakage current-induced charging of the electrically conductive connection and/or wherein the field-effect transistor structure further includes one or more electrically insulating layers configured to prevent leakage current-induced charging of the electrically conductive connection.

In example 22, the memory cell according to example 21 may optionally include that the second dielectric constant is at least three times greater than the first dielectric constant.

In example 23, the memory cell according to example 21 or 22 may optionally include that the first dielectric constant is less than or equal to 15 (in some aspects, less than or equal to 4) and that the second dielectric constant is greater than 15 (in some aspects, greater than 4).

In example 24, the memory cell according to any one of examples 21 to 23 may optionally further include any feature of the memory cell according to examples 1 to 20, where appropriate.

Example 25 is a memory cell including: a capacitive memory structure including a first electrode, a second electrode, and at least one remanent-polarizable layer disposed between the first electrode and the second electrode; a field-effect transistor structure including a channel region, a gate electrode, and a gate isolation including at least one gate isolation layer, the at least one gate isolation layer including a material having a dielectric constant greater than 4, wherein the at least one gate isolation layer is disposed between the gate electrode and the channel region; and an electrically conductive connection coupling the capacitive memory structure and the field-effect transistor structure with one another to form a capacitive voltage divider, wherein the electrically conductive connection is electrically floating, wherein the capacitive memory structure further includes one or more electrically insulating layers configured to prevent leakage current-induced charging of the electrically conductive connection and/or wherein the field-effect transistor structure further includes one or more electrically insulating layers configured to prevent leakage current-induced charging of the electrically conductive connection.

In example 26, the memory cell of example 25 may optionally further include that the gate isolation extends from a channel region of the field-effect transistor structure to a gate electrode of the field-effect transistor structure, and that the gate isolation is free of a silicon oxide layer (in some aspects, that the gate isolation is free of silicon oxide).

A structure being free of a layer may be understood, in some aspects, as that layer being present in the structure but the layer having a thickness less than 1 Å or less than 0.5 Å. Illustratively, the gate isolation being free of a silicon oxide layer may be understood as the gate isolation including a silicon oxide layer with thickness less than 1 Å or less than 0.5 Å. In some aspects, a structure being free of a material may be understood as the structure having a content in weight of that material less than 5% (for example less than 1% or less than 0.1%) with respect to the weight of the structure, e.g. a weight percentage (or weight ratio) of that material less than 5%. In some aspects, a structure being free of a material may be understood as the structure having a content in volume of that material less than 5% (for example less than 1% or less than 0.1%) with respect to the volume of the structure, e.g. a volume percentage (or volume ratio) of that material less than 5%. Illustratively, the gate isolation being free of silicon oxide may be understood, in some aspects, as the gate isolation having a content of silicon oxide in weight less than 5% (e.g., less than 1%, or less than 0.1 %) with respect to a weight of the gate isolation. The gate isolation being free of silicon oxide may be understood, in some aspects, as the gate isolation having a content of silicon oxide in volume less than 5% (e.g., less than 1%, or less than 0. 1%) with respect to a volume of the gate isolation.

Example 27 is a method of processing a memory cell, the method including: forming a field-effect transistor structure including a gate electrode; forming a metallization structure including one or more insulator layers and one or more source/drain contact structures embedded in the one or more insulator layers and configured to electrically contact the field-effect transistor structure, wherein forming the metallization structure includes forming a connection structure embedded in at least one of the one or more insulator layers, wherein the connection structure is configured electrically conductively connect a first electrode of a capacitive memory structure and the gate electrode of the field-effect transistor structure with one another and is electrically floating; forming the capacitive memory structure including the first electrode; and forming one or more additional electrically insulating structures configured to prevent leakage current-induced charging of the first electrode, the gate electrode, and the connection structure.

In example 28, the method according to example 27 may optionally further include that forming the capacitive memory structure is carried out after forming the connection structure, and that forming the metallization structure is carried out after forming the field-effect transistor structure.

In example 29, the method according to example 27 or 28 may optionally further include any feature of any one of examples 1 to 26, where appropriate.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A memory cell comprising:
a capacitive memory structure comprising a first electrode;
a field-effect transistor structure comprising a gate electrode;
one or more insulator layers;
one or more source/drain contact structures embedded in the one or more insulator layers to electrically contact the field-effect transistor structure; and
a connection structure embedded in at least one of the one or more insulator layers, wherein the connection structure electrically conductively connects the first electrode of the capacitive memory structure and the gate electrode of the field-effect transistor structure with one another and is electrically floating; and
one or more electrically insulating structures in addition to the one or more insulator layers configured to prevent a leakage current-induced charging of the first electrode, the gate electrode, and the connection structure, wherein the one or more electrically insulating structures comprise:
a memory charge-prevention layer disposed between the first electrode of the capacitive memory structure and at least one of the one or more insulator layers, the memory charge-prevention layer laterally surrounding the first electrode of the capacitive memory structure.

2. The memory cell according to claim 1,
wherein the first electrode is disposed between a first portion of the memory charge-prevention layer and a second portion of the memory charge-prevention layer.

3. The memory cell according to claim 1,
wherein the capacitive memory structure further comprises at least one remanent-polarizable layer, and wherein the memory charge-prevention layer further laterally surrounds the at least one remanent-polarizable layer.

4. The memory cell according to claim 3,
wherein the capacitive memory structure further comprises a second electrode, and wherein the memory charge-prevention layer further laterally surrounds the second electrode.

5. The memory cell according to claim 1,
wherein the memory charge-prevention layer comprises a first material that is different from a second material comprised in the at least one of the one or more insulator layers.

6. The memory cell according to claim 1,
wherein an interface of the at least one of the one or more insulator layers and the memory charge-prevention layer is disposed between the capacitive memory structure and the one or more source/drain contact structures.

7. The memory cell according to claim 1,
wherein the one or more electrically insulating structures comprise one or more electrically insulating layers at least partially surrounding at least one of a sidewall of the connection structure and/or a sidewall of the gate electrode.
7.
The memory cell according to claim 1,
wherein the one or more electrically insulating structures comprise one or more electrically insulating layers at least partially covering a surface of the gate electrode of the field-effect transistor structure, the surface facing the capacitive memory structure.

8. The memory cell according to claim 1,
wherein the one or more electrically insulating structures comprise one or more electrically insulating layers at least partially surrounding a sidewall of at least one source/drain contact structure of the one or more source/drain contact structures,
wherein the one or more electrically insulating layers are disposed between the at least one source/drain contact structure and the one or more insulator layers,
wherein the sidewall of the at least one source/drain contact structure faces at least one of the connection structure, the first electrode, or the gate electrode.

9. The memory cell according to claim 1,
wherein the field-effect transistor structure comprises a semiconductor layer and at least a first source/drain region and a second source/drain region disposed in the semiconductor layer,
wherein the one or more source/drain contact structures comprise a first source/drain contact structure and a second source/drain contact structure contacting the first source/drain region and the second source/drain region respectively.

10. The memory cell according to claim 1,
wherein the one or more electrically insulating structures comprise at least one first material that is different from a second material of the one or more insulator layers.

11. The memory cell according to claim 10,
wherein the first material of the one or more additional electrically insulating structures differs from the second material of the one or more insulator layers in at least one of the following properties: a crystal structure, a microstructure, a chemical element, and/or a chemical composition.

12. The memory cell according to claim 1,
wherein the capacitive memory structure further comprises one or more electrically insulating layers disposed between the first electrode and a second electrode of the capacitive memory structure, the one or more electrically insulating layers being configured to prevent leakage current-induced charging of the first electrode, the gate electrode, and the connection structure.

13. The memory cell according to claim 1,
wherein the field-effect transistor structure further comprises one or more electrically insulating layers disposed between a channel region and the gate electrode of the field-effect transistor structure, the one or more electrically insulating layers being configured to prevent leakage current-induced charging of the first electrode, the gate electrode, and the connection structure.

14. The memory cell according to claim 1,
wherein the capacitive memory structure comprises a second electrode and at least one remanent-polarizable layer arranged between the first electrode and the second electrode.

15. The memory cell according to claim 14,
wherein the at least one remanent-polarizable layer comprises at least one ferroelectric material.

16. A memory cell comprising:
a capacitive memory structure comprising a first electrode, a second electrode, and at least one remanent-polarizable layer disposed between the first electrode and the second electrode;
a field-effect transistor structure comprising a channel region, a gate electrode, and a first gate isolation layer and a second gate isolation layer,
the first gate isolation layer including a first material having a first dielectric constant and a first chemical composition, and the second gate isolation layer including a second material having a second dielectric constant and a second chemical composition,
wherein the first dielectric constant is different from the second dielectric constant and/or the first chemical composition is different from the second chemical composition,
wherein the first gate isolation layer and the second gate isolation layer are disposed between the gate electrode and the channel region; and
an electrically conductive connection coupling the capacitive memory structure and the field-effect transistor structure with one another to form a capacitive voltage divider, wherein the electrically conductive connection is floating,
wherein the capacitive memory structure further comprises one or more electrically insulating layers configured to prevent leakage current-induced charging of the electrically conductive connection, and/or
wherein the field-effect transistor structure further comprises one or more electrically insulating layers configured to prevent leakage current-induced charging of the electrically conductive connection.

17. The memory cell according to claim 16,
wherein the second dielectric constant is at least three times greater than the first dielectric constant.

18. The memory cell according to claim 16,
wherein the first dielectric constant is less than or equal to 15, and
wherein the second dielectric constant is greater than 15.

19. A method of processing a memory cell, the method comprising:
forming a field-effect transistor structure comprising a gate electrode;
forming a metallization structure comprising one or more insulator layers and one or more source/drain contact structures embedded in the one or more insulator layers and configured to electrically contact the field-effect transistor structure, wherein forming the metallization structure comprises forming a connection structure embedded in at least one of the one or more insulator layers, wherein the connection structure is configured electrically conductively connect a first electrode of a capacitive memory structure and the gate electrode of the field-effect transistor structure with one another and is electrically floating;
forming the capacitive memory structure comprising the first electrode; and forming one or more additional electrically insulating structures configured to prevent leakage current-induced charging of the first electrode, the gate electrode, and the connection structure, wherein forming the one or more additional electrically insulating structures comprises; and
forming a memory charge-prevention layer disposed between the first electrode of the capacitive memory structure and at least one of the one or more insulator layers, the memory charge-prevention layer laterally surrounding the first electrode of the capacitive memory structure.

20. The method according to claim 19,
wherein forming the memory charge-prevention layer comprises covering a sidewall of the first electrode facing the one or more source/drain contact structures.
